(19) United States
(12) Patent Application Publication
(10) Pub. No.: US 2025/0298517 A1
(43) Pub. Date: Sep. 25, 2025

(54) NON-VOLATILE MEMORY DEVICE, A STORAGE DEVICE INCLUDING THE NON-VOLATILE MEMORY DEVICE AND A METHOD OF OPERATING THE STORAGE DEVICE

(71) Applicant: Samsung Electronics Co., Ltd., Suwon-si (KR)

(72) Inventors: Donghyun Seo, Suwon-si (KR); JAE-DUK YU, Suwon-si (KR); SANG SOO PARK, Suwon-si (KR); JONGHOON PARK, Suwon-si (KR)

(21) Appl. No.: 19/029,778

(22) Filed: Jan. 17, 2025

(30) Foreign Application Priority Data
Mar. 22, 2024 (KR) 10-2024-0039898

(51) Int. Cl. G06F 3/06

(52) U.S. Cl. CPC G06F 3/0619; G06F 3/0659; G06F 3/0673

(57) ABSTRACT

Provided are a non-volatile memory device, a storage device including the non-volatile memory device, and a method of operating the storage device. The non-volatile memory device includes a memory cell array including first and second sub-blocks that are respectively formed from first and second portions of memory cell strings that extend through a plurality of wordlines stacked on a substrate, the first and second sub-blocks each being selectable as a unit of an erase operation; and control logic configured to calculate an off-cell count based on a first voltage for a plurality of memory cells in the first sub-block, calculate an on-cell count based on a second voltage for the plurality of memory cells, and control an operation for the first sub-block to be performed based on an operating condition corresponding to disturb information generated by the off-cell count and the on-cell count.

### CROSS-REFERENCE TO RELATED APPLICATION

This application claims priority to and the benefit of Korean Patent Application No. 10-2024-0039898 filed in the Korean Intellectual Property Office on Mar. 22, 2024, the entire contents of which are incorporated herein by reference.

### BACKGROUND OF THE DISCLOSURE

### (a) Field of the Disclosure

The present disclosure relates to a non-volatile memory device, a storage device including the non-volatile memory device, and a method of operating the storage device.

### (b) Description of the Related Art

Memory devices are used to store data, and are divided into volatile memory devices and non-volatile memory devices. As an example of a non-volatile memory device, a flash memory device may be used for long-term data storage in a cell phone, digital camera, portable information terminal (PDA), mobile computer device, fixed computer device, and other devices.

To improve the storage capacity and integration of non-volatile memory devices, non-volatile memory devices in which memory cells are stacked in a three-dimensional structure, such as 3D NAND flash memory, are being investigated.

As a result, non-volatile memory devices are being developed with the trend of increasing the capacity of a single memory block. However, as memory blocks become larger, it is difficult for conventional block-unit control techniques and algorithms to provide adequate performance for the increased block capacity.

### SUMMARY OF THE DISCLOSURE

The present disclosure can provide a non-volatile memory device that improves reliability issues due to disturb deterioration caused by an operation of an adjacent sub-block, a storage device including the non-volatile memory device, and a method of operating the storage device.

The present disclosure can provide a storage device that improves performance by reducing the number of read reclaim operations, and a method of operating the storage device.

An embodiment of the present disclosure provides a non-volatile memory device including: a memory cell array including first and second sub-blocks that are respectively formed from first and second portions of memory cell strings that extend through a plurality of wordlines stacked on a substrate, the first and second sub-blocks each being selectable as a unit of an erase operation, and control logic configured to calculate an off-cell count based on a first voltage for a plurality of memory cells in the first sub-block, calculate an on-cell count based on a second voltage for the plurality of memory cells, and control an operation for the first sub-block to be performed based on an operating condition corresponding to disturb information generated by the off-cell count and the on-cell count.

Another embodiment of the present disclosure provides a storage device including a non-volatile memory device including a memory cell array including first and second sub-blocks that are divided respectively formed from first and second portions of memory cell strings that extend through a plurality of wordlines stacked on a substrate, the first and second sub-blocks each being selectable as a unit of an erase operation, and control logic configured to generate disturb information for the first sub-block based on an on-cell count and an off-cell count for a plurality of memory cells in the first sub-block, and adjust an operating condition for the first sub-block based on the disturb information, and a storage controller configured to log a first command for the second sub-block, and provide the non-volatile memory device with a disturb check command for the disturb information based on log information from a logging operation.

Still another embodiment of the present disclosure provides a method of operating a storage device, the method including logging a command of a first sub-block to monitor a disturb circumstance of a second sub-block connected to a first bitline connected to the first sub-block. The first and second sub-blocks may respectively be formed from first and second portions of memory cell strings that extend through a plurality of wordlines stacked on a substrate, providing a disturb check command for the second sub-block based on a log operation for the command to a non-volatile memory device including the first and second sub-blocks, generating disturb information by calculating based on an on-cell count and an off-cell count for a memory cell of a first wordline in the second sub-block, storing the disturb information, and performing an operation on the second sub-block based on an operating condition corresponding to the disturb information.

### BRIEF DESCRIPTION OF THE DRAWINGS

FIG. 1 is a block diagram illustrating an electronic device according to an embodiment.

FIG. 2 is a block diagram illustrating a storage device according to an embodiment.

FIG. 3 is a block diagram illustrating a storage controller according to an embodiment.

FIG. 4 is a block diagram illustrating a non-volatile memory device according to an embodiment.

FIG. 5 is a circuit diagram illustrating a three-dimensional structure of a memory cell array of FIG. 4 according to an embodiment.

FIG. 6 is a diagram illustrating an operation and a status of one sub-block of FIG. 5.

FIG. 7 is a diagram illustrating an operating condition table according to an embodiment.

FIG. 8 is a perspective view illustrating the memory cell array of FIG. 4.

FIG. 9 is a top plan view illustrating the memory cell array of FIG. 4.

FIG. 10 is a cross-sectional view of a channel hole according to an embodiment.

FIG. 11 is a cross-sectional view of a channel hole according to an embodiment.

FIG. 12 is a flowchart illustrating a method of operating a storage device according to an embodiment.

FIGS. 13 to 16 are diagrams illustrating the method of operating the storage device according to the embodiment.

FIG. 17 is a flowchart illustrating the method of operating the storage device according to the embodiment.

FIGS. 18 and 19 are diagrams illustrating the method of operating the storage device according to the embodiment.

FIG. 20 is a diagram illustrating an operating condition table according to an embodiment.

FIG. 21 is a flowchart illustrating a method of operating a storage device according to an embodiment.

FIG. 22 is a block diagram illustrating a data storage device including the non-volatile memory device according to the embodiment.

FIG. 23 is a block diagram illustrating a calculating system including the non-volatile memory device according to the embodiment.

### DETAILED DESCRIPTION OF THE EMBODIMENTS

In the following detailed description, only certain embodiments of the present disclosure have been illustrated and described, simply by way of illustration. However, the present disclosure may be variously implemented and is not limited to the following embodiments.

The drawings and description are to be regarded as illustrative in nature and not restrictive. Like reference numerals designate like elements throughout the specification.

In addition, unless explicitly described to the contrary, the word “comprise”, and variations such as “comprises” or “comprising”, will be understood to imply the inclusion of stated elements but not the exclusion of any other elements.

Furthermore, a specific number written in a claim, even if expressly cited within a claim, should not be understood to mean that the specific number limitation does not exist in a claim where no such citation exists. For example, to help understanding, the phrases “at least one” and “one or more” may be included in subsequent dependent claims. However, the use of such phrases should not be understood as a limitation described by the article “one” which, for the sake of illustration, is indefinite.

Furthermore, where a phrase such as “at least one of A, B, or C”, is used, the phrase may be well understood by those skilled in the art (that is, “a system including at least one of A, B, or C” includes, but is not limited to, the meaning of A alone, B alone, C alone, A and B, A and C, B and C, and/or A, B, and C together).

Alternatively, in the detailed description or claims or drawings, letters and/or phrases having two or more separate selectable terms should be considered as having the possibility to include one, any one of two, or both terms. For example, the phrase “A or B” should be understood to include the possibility of “A”, “B”, or “A and B”.

As used herein, terms, such as “module,” “unit,” and “part”, are intended to refer to components that perform at least one function or operation, which components may be implemented in hardware or software or as a combination of hardware and software.

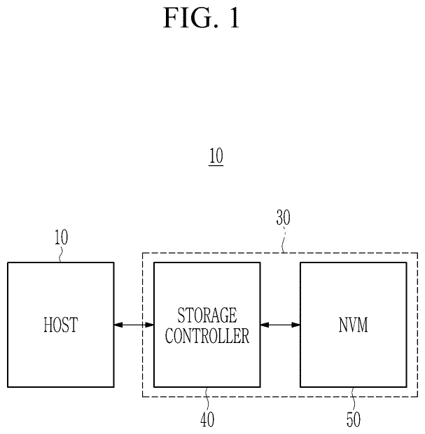

FIG. 1 is a block diagram illustrating an electronic device according to an embodiment.

Referring to FIG. 1, an electronic device 10 may include a host 20 and a storage device 30. The storage device 30 may include a storage controller 40 and at least one non-volatile memory device 50. The host 20 has overall control over an operation of the storage device 30.

The storage controller 40 may exchange signals for commands, addresses, and data with the host 20. According to the embodiment, the host 20 may provide a request that includes commands, addresses, and data to the storage device 30.

The storage controller 40 may write data to the non-volatile memory device 50 or read data from the non-volatile memory device 50 in response to the request from the host 20.

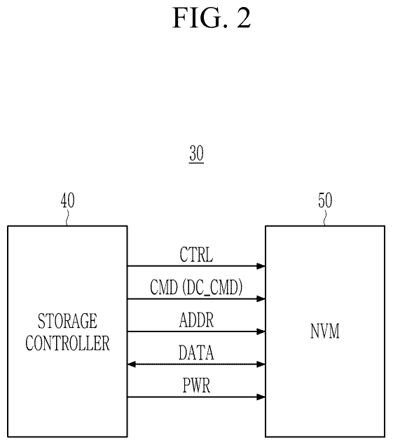

FIG. 2 is a block diagram illustrating a storage device according to an embodiment.

Referring to FIG. 2, the storage device 30 may include a storage controller 40 and at least one non-volatile memory device 50. In the embodiment, each of the storage controller 40 and non-volatile memory device 50 may be provided as one chip, one package, one module, and the like. Alternatively, the storage controller 40 and the non-volatile memory device 50 may be mounted based on various packages and provided as a storage device, such as a memory card.

The non-volatile memory device 50 may perform erase, program, read operations, or the like under the control of the storage controller 40. To this end, the non-volatile memory device 50 may be provided with commands CMD, addresses ADDR, and data DATA via input and output lines. Further, the non-volatile memory device 50 may receive a control signal CTRL via the control line. The non-volatile memory device 50 may also receive power PWR from the storage controller 40.

The storage controller 40 may collect and log deterioration information for the non-volatile memory device 50, at the level (e.g., unit) of a sub-block. For example, the deterioration information may include program/erase cycles, read counts, erase counts, program counts, wear level counts, elapsed time, and operating temperature.

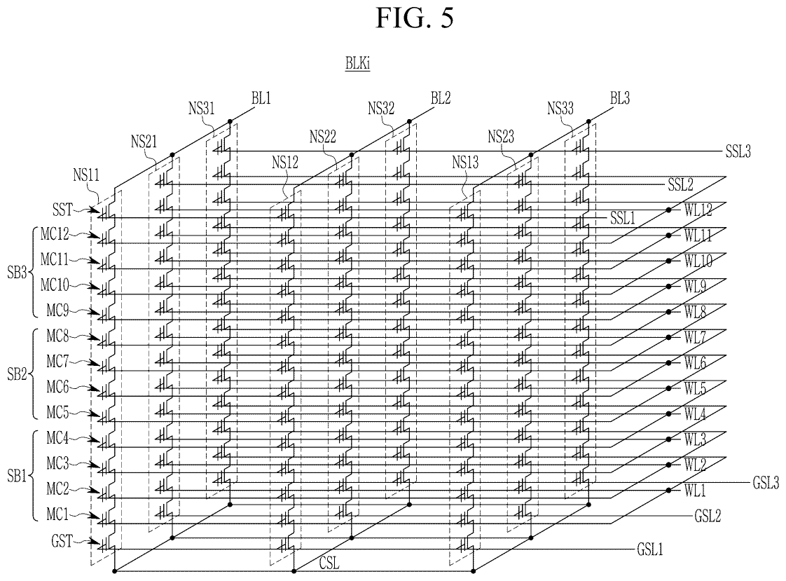

In accordance with an embodiment, the storage controller 40 may manage the non-volatile memory device 50 into a plurality of small sub-blocks separated by wordlines within a single stack. A specific description of the sub-blocks in the present disclosure will be provided below with reference to FIGS. 5, 9, and 10.

In accordance with an embodiment, the storage controller 40 may log deterioration information associated with the disturb at the level (e.g., unit) of a sub-block, to monitor sub-blocks of the non-volatile memory device 50.

Based on the logged deterioration information, the storage controller 40 may provide the non-volatile memory device 50 with a disturb check command DC_CMD for a sub-block that is determined to be in a disturb circumstance.

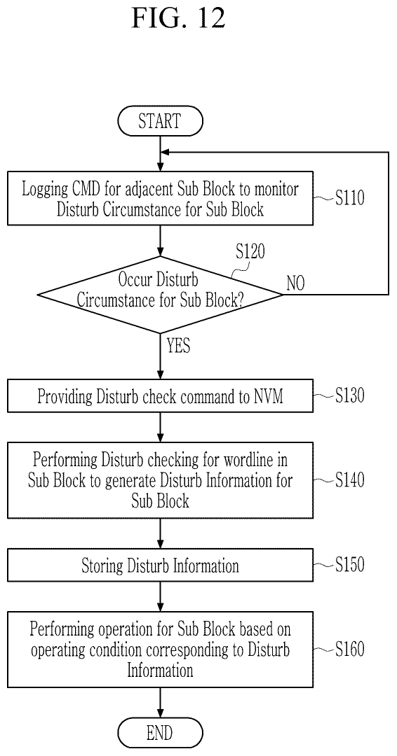

In accordance with an embodiment, the non-volatile memory device 50 may be provided with the disturb check command DC_CMD from the storage controller 40 as an example of a command CMD. The non-volatile memory device 50 according to an embodiment, in response to the provision of the disturb check command DC_CMD, may perform a disturb check operation to determine whether the sub-block is disturbed. A specific description of the disturb check operation of the non-volatile memory device 50 will be described below with reference to FIGS. 12 to 21.

The non-volatile memory device 50 according to the embodiment may adjust operating conditions for operations such as erase, program, or read, for a targeted sub-block based on a shifted distribution of the threshold voltage for memory cells within the sub-block that is varied by the disturb.

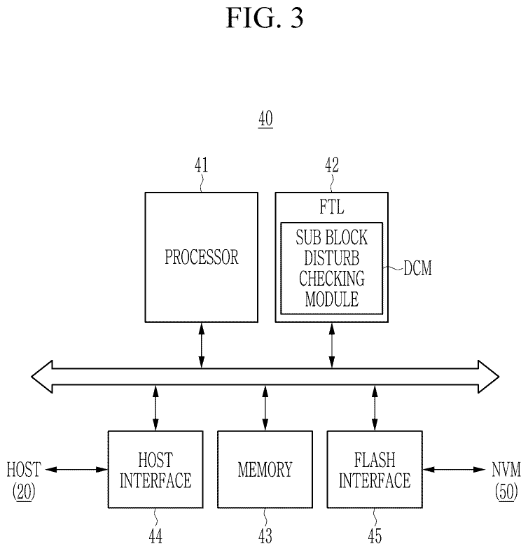

FIG. 3 is a block diagram illustrating details of the storage controller 40 according to an embodiment.

Referring to FIGS. 1 to 3, the storage controller 40 may include a processor 41, a flash translation layer 42, a memory 43, a host interface 44, and a flash interface 45.

The processor 41 may control various operations of the storage controller 40. The memory 43 may operate as a buffer memory, a cache memory, and an operational memory for the processor 41. Depending on the embodiment, the memory 43 may include, but is not limited to, DRAM, SRAM, and the like.

The flash translation layer 42 (hereinafter referred to as “FTL”) may provide an interface between the host 20 and the non-volatile memory device 50 to ensure that the non-volatile memory device 50 is utilized efficiently. In accordance with some embodiments, the FTL 42, as a memory management module, may perform address mapping operations, garbage collection operations, wear leveling operations, read reclaim operations, log operations for deterioration information at the level of a sub-block, and the like.

In accordance with an embodiment, the FTL 42 may include a sub-block disturb check module DCM. The sub-block disturb check module DCM may log operations on sub-blocks included in the non-volatile memory device 50 to monitor disturb circumstances for the sub-blocks.

In accordance with an embodiment, the sub-block disturb check module DCM may log commands for adjacent sub-blocks connected to the same bit line to monitor the disturb circumstance of the sub-block.

In accordance with an embodiment, the sub-block disturb check module DCM may determine a disturb circumstance for the sub-block based on the log information, and based on the determination, the storage controller 40 may provide a disturb check command DC_CMD to the non-volatile memory device 50.

In FIG. 3, the sub-block disturb check module DCM is illustrated as being included in the FTL 42, but in accordance with some embodiments, the sub-block disturb check module DCM may perform the operations describe above as a separate module, and/or may be included in other configurations.

In accordance with some embodiments, the FTL 42 may be provided in hardware form as a dedicated circuit, but is not limited thereto. In accordance with some embodiments, the FTL 42 may be provided in software form and, when the FTL 42 is provided in software form, the FTL 42 may be loaded into the memory 43 and operated by the processor 41.

For example, the FTL 42 and the address mapping table (not illustrated) may be stored in the memory 43. The FTL 42 and the address mapping table (not illustrated) stored in the memory 43 may be operable by the processor 41.

The host interface 44 may allow communication between the host 20 and the storage controller 40. For example, the host interface 44 may include various interfaces, such as universal serial bus (USB), multimedia card (MMC), peripheral component interconnection (PCI), PCI-express (PCI-E), advanced technology attachment (ATA), serial-ATA, parallel-ATA, small computer small interface (SCSI), enhanced small disk interface (ESDI), integrated drive electronics (IDE), mobile industry processor interface (MIPI), and NVMe. The storage controller 40 may communicate with the non-volatile memory device 50 via the flash interface 45.

The memory cells included in the non-volatile memory device 50 have physical characteristics such that the distribution of the threshold voltage changes due to factors, such as program elapsed time, temperature, and disturbs due to the operation of adjacent sub-blocks. For example, the factors described above may cause errors in the data stored in the non-volatile memory device 50.

Although not illustrated, the storage controller 40 may use various error correction techniques to correct these errors, and for example, the storage controller 40 may include an error correction code (ECC) engine. However, in some cases, error correction may not be possible by the ECC engine, in which case the FTL 42 may perform a read reclaim operation to mitigate the error. The read reclaim operation may be based on deterioration information.

The read reclaim operation may be a copy back operation that moves the data stored in the memory block or sub-block to another memory block or another sub-block before an uncorrectable error occurs. In accordance with an embodiment, the FTL 42 may provide a command CMD to the non-volatile memory device 50 such that a read reclaim operation for the sub-block is performed before an uncorrectable error occurs in the sub-block.

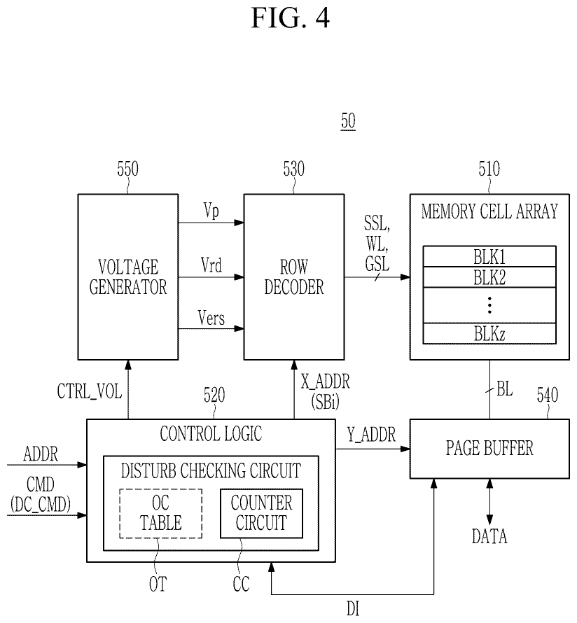

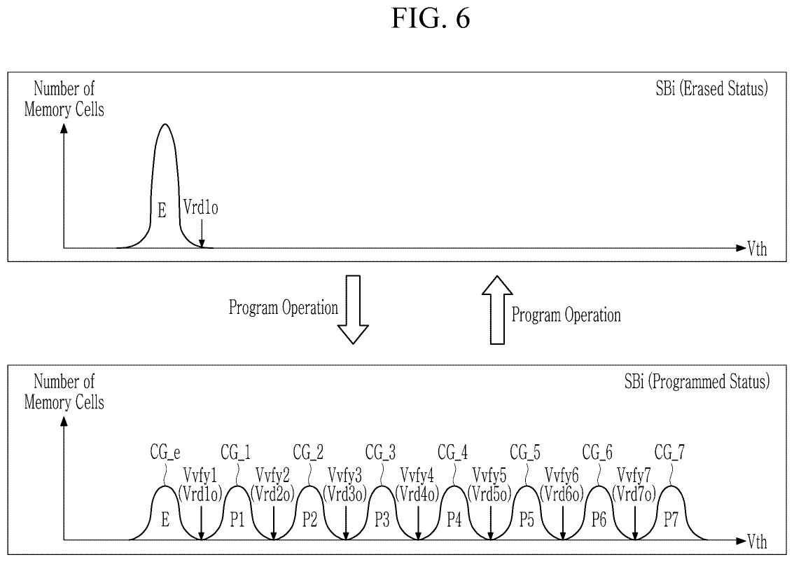

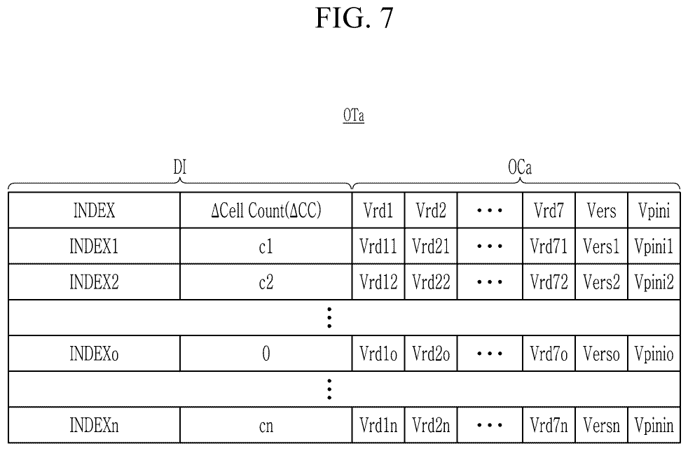

FIG. 4 is a block diagram illustrating a non-volatile memory device according to an embodiment. FIG. 5 is a diagram illustrating a three-dimensional structure of a memory cell array of FIG. 4 according to an embodiment. FIG. 6 is a diagram illustrating an operation and a status of one sub-block of FIG. 5. FIG. 7 is a diagram illustrating an operating condition table according to an embodiment.

Referring now to FIGS. 1 to 4, the non-volatile memory device 50 may include a memory cell array 510, control logic 520, a row decoder 530, a page buffer circuit 540, and a voltage generator 550. Although not illustrated in FIG. 4, according to the embodiment, the non-volatile memory device 50 may further include a memory interface circuit, and may further include column logic, a pre-decoder, a temperature sensor, a command decoder, an address decoder, and the like.

The memory cell array 510 may be connected to the page buffer circuit 540 via a bitline BL, and may be connected to the row decoder 530 via a plurality of wordlines WL, a plurality of string select lines SSL, and a plurality of ground select lines GSL, and the like.

The memory cell array 510 may include a plurality of memory blocks BLK1 to BLKz (where z is an integer equal to or greater than 3). Each of the plurality of memory blocks BLK1 to BLKz may include a plurality of pages, and each of the plurality of pages may include a plurality of memory cells.

In accordance with an embodiment, the plurality of memory blocks BLK1 to BLKz may be a single-level cell block including a single-level cell SLC storing 1 bit of data, a multi-level cell block including a multi-level cell MLC storing at least 2 bits of data, a triple-level cell block including a triple-level cell TLC, or a quad-level cell block including a quad-level cell QLC.

Referring further to FIG. 5, the memory block BLKi illustrated in FIG. 5 may be a respective one of the plurality of memory blocks BLK1 to BLKz shown in FIG. 4, and may represent a three-dimensional memory block formed in a three-dimensional structure on a substrate. Hereinafter, the description of the plurality of memory blocks BLK1 to BLKz may be substituted for the description of the memory block BLKi in FIG. 5. In an example, the plurality of memory cell strings included in the memory block BLKi may be formed in a direction perpendicular to the substrate.

The memory block BLKi may include a plurality of memory cell strings NS11 to NS33 connected between the bit lines BL1, BL2, and BL3 and a common source line CSL. Each of the plurality of memory cell strings NS11 to NS33 may include a string select transistor SST, a plurality of memory cells MC1, MC2, . . . , and MC12, and a ground select transistor GST.

The string select transistor SST may be connected to corresponding string select lines SSL1, SSL2, and SSL3. The plurality of memory cells MC1, MC2, . . . , and MC12 may be connected to corresponding wordlines of the plurality of wordlines WL1, WL2, . . . , and WL12 stacked on the substrate, respectively. The ground select transistor GST may be connected to the corresponding ground selection lines GSL1, GSL2, and GSL3. The string select transistor SST may be connected to a corresponding bit line BL1, BL2, and BL3, and the ground select transistor GST may be connected to the common source line CSL. The wordline of the same height (for example, WL1) may be connected in common, and the ground select lines GSL1, GSL2, and GSL3 and the string select lines SSL1, SSL2, and SSL3 may be separate.

In order to improve performance of block-unit control techniques as the size of memory blocks is made larger, the individual memory block BLKi described above may be divided into a plurality of smaller sub-blocks SB1, SB2, and SB3. Each of the plurality of sub-blocks SB1, SB2, and SB3 may be divided by a plurality of wordlines WL1, WL2, . . . , and WL12 stacked on the substrate. Each of the plurality of sub-blocks SB1, SB2, and SB3 is a unit of erase operation and may be erased independently of other sub-blocks within the memory block BLKi. Each of the plurality of sub-blocks SB1, SB2, and SB3 may be subjected to an erase operation in which all of the memory cells of the sub-block are erased together (i.e., those memory cells of a sub-block that are not in an erase state are set to the erase state by the erase operation). A sub-block may correspond to a minimum unit of erase such that an erase operation to just a portion of a sub-block may not be performed (i.e., without also subjecting the remainder of the sub-block to the erase operation). Depending on the selection criteria during an erase operation, only one sub-block of a block may be erased in an erase operation or several (or all) of the sub-blocks of a block may be erased in an erase operation.

The first sub-block SB1 may include memory cells connected to the first to fourth wordlines WL1, WL2, WL3, and WL4 among the memory cells included in the memory block BLKi. The second sub-block SB2 may include memory cells connected to the fifth to eighth wordlines WL5, WL6, WL7, and WL8 among the memory cells included in the memory block BLKi. The third sub-block SB3 may include memory cells connected to the ninth to twelfth wordlines WL9, WL10, WL11, and WL12 among the memory cells included in the memory block BLKi. Depending on the embodiment, one or more of the plurality of sub-blocks SB1, SB2, and SB3 may be selected and erased simultaneously. To do so, the row decoder 530 may provide a bias to erase the memory cells at the level of a sub-block SBi. In an embodiment, adjacent sub-blocks within the same memory block may be floated while the erase operation for one sub-block is in progress (e.g., subOblock SB1 and SB3 may be floated while memory cells of sub-block SB2 are erased by the erase operation). Floating of a sub-block as described herein may be implemented by floating wordlines of that sub-block.

The sub-block SBi is any one of a plurality of sub-blocks SB1, SB2, and SB3, and a description of sub-block SBi may be substituted for a common description of the plurality of sub-blocks SB1, SB2, and SB3 hereinafter. In FIG. 5, it is illustrated that the memory block BLKi includes three sub-blocks, but the number of sub-blocks illustrated is for illustrative purposes only and does not limit the technical ideas of the present disclosure. Accordingly, the plurality of sub-blocks may include any number of sub-blocks.

Referring again to FIG. 4, the control logic 520 may receive a command CMD and an address ADDR from the storage controller 40 and may control an erase operation, a program operation, and a read operation of the non-volatile memory device 50 based on the command CMD and the address ADDR.

The control logic is a circuit (a portion of the integrated circuit of the non-volatile memory device 50) that forms an internal controller to control the various operations of the non-volatile memory device 50, where such control may including timing, selection, operation conditions, etc. For example, the control logic 520 may generate various control signals based on the command CMD, and may generate a row address X_ADDR and a column address Y_ADDR based on the address ADDR. The control logic 520 may provide a voltage control signal CTRL_VOL to the voltage generator 550. The control logic 520 may provide the row address X_ADDR to the address decoder 530 and provide the column address Y_ADDR to the page buffer circuit 540.

The row decoder 530 may be connected to the memory cell array 510 via the string select line SSL, the plurality of wordlines WL, and the ground select line GSL.

The voltage generator 550 may generate wordline voltages required for the operation of the non-volatile memory device 50 based on a voltage control signal CTRL_VOL provided from the control logic 520. The wordline voltages generated by the voltage generator 550 may be applied to the plurality of wordlines WL via the row decoder 530.

Referring further to FIG. 6, during the erase operation for the sub-block SBi, the voltage generator 550 may apply an erase voltage Vers to the well or substrate of the memory block and apply a ground voltage to the wordlines of the selected sub-block. According to the embodiment, during the erase operation for the sub-block SBi, the voltage generator 550 may apply an erase voltage Vers to the wordlines of the unselected sub-blocks or the wordlines of the unselected sub-blocks may be floated. During an erase verification operation, the voltage generator 550 may apply an erase verification voltage to the wordlines of the selected sub-block SBi or may apply an erase verification voltage on a wordline basis. Referring to FIG. 6 for illustrative purposes, the voltage generator 550 may provide a first initial read voltage Vrd1o to the wordlines of the sub-block SBi as the erase verification voltage for an erased status E.

During a program operation, the voltage generator 550 may apply a program voltage Vp to the selected wordline and apply a program pass voltage to non-selected wordlines. In addition, during the program verification operation, the voltage generator 550 may apply a program verification voltage to the selected wordline and apply a verification pass voltage to non-selected wordlines. Referring to FIG. 6 for illustrative purposes, according to an embodiment, the voltage generator 550 may apply a program voltage Vp to the selected wordline during a program loop and provide first to seventh program verification voltages Vvfy1 to Vvfy7 to verify the programmed status (e.g., program state) of the memory cell. According to an embodiment, the first to seventh program verification voltages Vvfy1 to Vvfy7 may be sequentially high. After completion of the program operation, the memory cells in the sub-block SBi may be divided into an erase cell group CG_e and first to seventh cell group CG_1 to CG_7 based on a varied threshold voltage Vth and the first to seventh program verification voltages Vvfy1 to Vvfy7. Each of the memory cells in the erase cell group CG_e, and the first to seventh cell groups CG_1 to CG_7 may have an erased status (or erase state) E, and sequentially higher states P1 to P7. In FIG. 6, the present disclosure has been described based on the premise that the memory cells in the sub-block SBi are triple-level cells TLC having the erased status E and the sequentially higher states P1 to P7, but this is for illustrative purposes only, and the technical ideas of the present disclosure are not limited with regard to the type of memory cells.

During the read operation, the voltage generator 550 may apply a read voltage Vrd to the selected wordline and apply a read pass voltage to the non-selected wordlines. Referring to FIG. 6 for illustrative purposes, during the read operation, the voltage generator 550 may apply first to seventh initial read voltages Vrd1o to Vrd7o to the selected wordlines. Based on the first to seventh initial read voltages Vrd1o to Vrd7o, the page buffer circuit 540 may check the programmed status of the memory cell in the selected wordline and read the data DATA stored in the memory cell. According to an embodiment, the first to seventh initial read voltages Vrd1o to Vrd7o may be equal to voltage levels of the first to seventh program verification voltages Vvfy1 to Vvfy7,respectively.

Referring again to FIG. 4, the page buffer circuit 540 may be connected to the memory cell array 510 via a plurality of bitlines BL. Some of the bitlines among the plurality of bitlines BL may be selected in response to a column address Y-ADDR received from the control logic 520. During the program operation or the read operation, the page buffer circuit 540 may operate as a sense amplifier to sense the data DATA stored in the memory cell array 510. On the other hand, during the program operation, the page buffer circuit 540 may operate as a write driver to input data DATA desired to be stored in the memory cell array 510. The page buffer circuit 540 may store the data DATA read from the memory cell array 510, or may store the data DATA to be written to the memory cell array 510.

In accordance with an embodiment, the control logic 520 may include a disturb check circuit 521 and may receive a disturb check command DC_CMD from the storage controller 40. The disturb check circuit 521 may control configurations of the non-volatile memory device 50 to check for distribution shift of the threshold voltage for the memory cells at the level (e.g., unit) of a sub-block.

In accordance with an embodiment, the disturb check circuit 521 may generate disturb information DI based on the shifted distribution of the threshold voltage for the memory cells within the sub-block SBi. In accordance with an embodiment, the disturb check circuit 521 may control configurations of the non-volatile memory device 50 to adjust operating conditions of the read operation, the erase operation, and the program operation for the sub-block SBi based on the disturb information DI.

In accordance with an embodiment, the disturb check circuit 521 may include a counter circuit CC, and an operating condition table OT. In accordance with an embodiment, the counter circuit CC may calculate a change value of the memory cells that are on-cell or off-cell based on a specific voltage to check for the distribution shift in the threshold voltage for the memory cells of the sub-block SBi.

For example, the counter circuit CC may count the memory cells determined to be on-cells based on a first program verification voltage Vvfy1 or a first initial read voltage Vrd10 determining a first status P1 for one wordline in the sub-block SBi, and then calculate the change value of the memory cells determined to be on-cells by the distribution shift in the threshold voltage and generate the off-cell count.

For example, the counter circuit CC may count the memory cells determined to be off-cells based on a seventh program verification voltage Vvfy7 or a seventh initial read voltage Vrd7o determining a seventh status P7 for one wordline in the sub-block SBi, and then calculate the change value of the memory cells determined to be off-cells by the distribution shift of the threshold voltage to generate an on-cell count.

In accordance with an embodiment, the counter circuit CC may

calculate based on the off-cell count and the on-cell count to generate a cell count change value. According to an embodiment, the counter circuit CC may check the distribution shift of the threshold voltage for the memory cell of the sub-block SBi based on the cell count change value. According to an embodiment, the disturb check circuit 521 may generate the disturb information DI based on the cell count change value and the operating condition table OT.

In accordance with an embodiment, the control logic 520 may control configurations of the non-volatile memory device 50 to perform the read operation, the erase operation, and the program operation for the sub-block SBi based on the operating condition information corresponding to the disturb information DI.

Referring further to FIG. 7, an operating condition table OTa according to an embodiment may include disturb information DI, and an operating conditions OCa corresponding to the disturb information DI. The operating conditions OCa may include first to seventh read voltages Vrd1 to Vrd7, an erase voltage Vers, and a first program voltage Vpini. In some examples, the operating conditions OCa may include other information, such as time to represent different erase voltage pulse widths and/or different programming pulse widths. As discussed herein, an index (one of INDEX1 to INDEXn) may be selected for a particular sub-block based on disturb information DI corresponding to that sub-block, and the operating conditions OCa corresponding to that index (and the disturb information DI) may be used in subsequent operations for that sub-block.

According to an embodiment, the operating condition table OTa may include first to n^{th} indexes INDEX1 to INDEXn (where n is a natural number equal to or greater than 2) that is the disturb information DI, and first to n^{th} cell count change values c1 to cn that are the cell count change values ΔCC corresponding to the first to n^{th} indexes INDEX1 to INDEXn, respectively. In accordance with an embodiment, the operating condition table OTa may include the cell count change values ΔCC itself as disturb information DI.

According to an embodiment, a cell count change value ΔCC may be an integer including zero, a negative integer, or a positive integer. According to an embodiment, the first to n^{th} cell count change values c1 to cn corresponding to the first to n^{th} indices INDEX1 to INDEXn may sequentially increase in value. According to an embodiment, closer to the first index INDEX1 may imply a distribution decrease in the threshold voltage for the memory cells in the sub-block SBi, and closer to the n^{th} index INDEXn may imply a distribution increase in the threshold voltage for the memory cells in the sub-block SBi. The first to n^{th} indexes INDEX1 to INDEXn may include a zero index INDEXo corresponding to a cell count change value ΔCC of zero.

According to an embodiment, the first to seventh read voltages Vrd1 to Vrd7 are read voltages Vrd provided to the wordlines to read data stored in memory cells that are triple level cells TLC, which may sequentially increase with respect to each other. In accordance with an embodiment, the first program voltage Vpini may be a program voltage applied to the selected wordline in the initial program loop in the program operation. Subsequent program voltages of the program loop may be selected based on the first program voltage Vpini. For example, a program loop may comprise a series of program voltages, e.g., program voltage pulses, applied to selected wordlines to program selected memory cells to a particular state. The voltage of each program voltage pulse may be increased by a predetermined amount with respect to the previously applied program voltage pule. The first program voltage Vpini may be the voltage of the first program voltage pulse of a program loop. Note that several program loops may be performed in a programming operation, where each program loops is associated with a different data state (a voltage threshold in a range associated with a value of one or more bits) to be obtained by selected memory cells of the selected wordline. In some examples, operating conditions OCa may include several different first program voltage Vpini, each associated with a different program loop(s) for programming to different data state(s).

Referring to FIG. 7 for illustrative purposes, the operating condition table OTa may include operating condition information including a first index INDEX1, a first cell count change value c1, and first_1 to seventh_1 read voltages Vrd11 to Vrd71, a first erase voltage Vers1, and a first first program voltage Vpini1 corresponding to the first index INDEX1.

The operating condition table OTa may include operating condition information including a second index INDEX2, a second cell count change value c2, and first_2 to seventh_2 read voltages Vrd12 to Vrd72, a second erase voltage Vers2, and a second first program voltage Vpini2 corresponding to the second index INDEX2.

The operating condition table OTa may include operating condition information including a zero index INDEXo, zero, and first to seventh initial read voltages Vrd10 to Vrd70, an initial erase voltage Verso, and an initial first program voltage Vpinio corresponding to the zero index INDEXo. In accordance with an embodiment, the operating conditions OCa corresponding to the zero index INDEXo may be voltages of the same values as the operating voltages of the read operation, the erase operation, and the program operation that is set at the beginning (e.g., for a block that has just been set to an erase state) prior to adjustment by the disturb check circuit 521.

The operating condition table OTa may include operating condition information including a n^{th} index INDEXn, a n^{th} cell count change value cn, and first_n to seventh_n read voltages Vrdin to Vrd7n, a n^{th} erase voltage Versn, and a n^{th} first program voltage Vpinin corresponding to the n^{th} index INDEXn.

Depending on the embodiment, as an index is closer to the first index INDEX1, the first to seventh read voltages Vrd1 to Vrd7 corresponding to the index may be respectively lower than corresponding first to seventh read voltages. For example, the first_1 read voltage Vrd11 may be lower than the first_2 read voltage Vrd12, and the seventh_1 read voltage Vrd71 may be lower than the seventh_2 read voltage Vrd72.

According to an embodiment, as an index is closer to the first index

INDEX1, the erase voltage Vers corresponding to the index may be lower. For example, the first erase voltage Vers1 may be lower than the second erase voltage Vers2.

Depending on the embodiment, as an index is closer to the first index INDEX1, the first program voltage Vpini corresponding to the index may be higher. For example, the first first program voltage Vpini1 may be higher than the second first program voltage Vpini2.

In accordance with an embodiment, the operating condition table OTa may be stored as fuse data stored by a fusing operation or an anti-fusing operation. According to embodiments, the operational condition information in the operational condition table OTa may be, but is not limited to, one-time programmable (OTP) data. In accordance with an embodiment, the operational condition information in the operational condition table OTa may be stored in the memory cell array 510, along with the disturb information DI for the sub-block SBi.

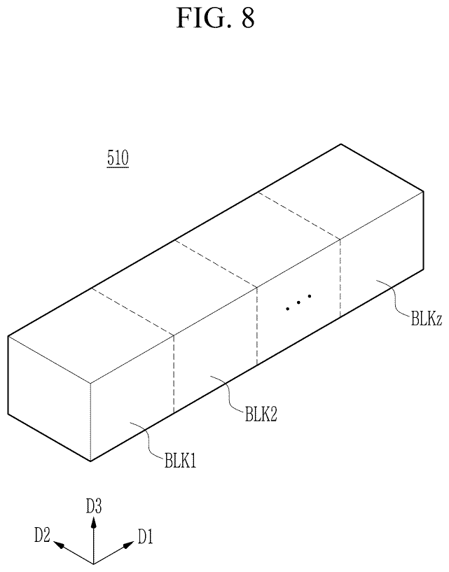

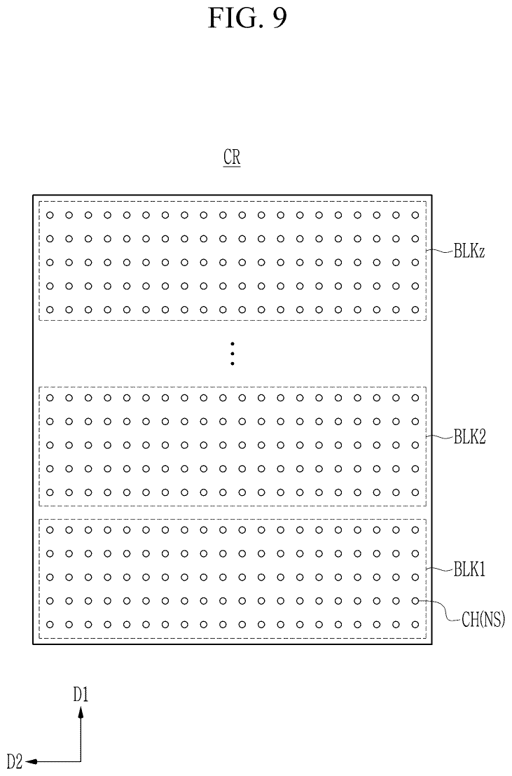

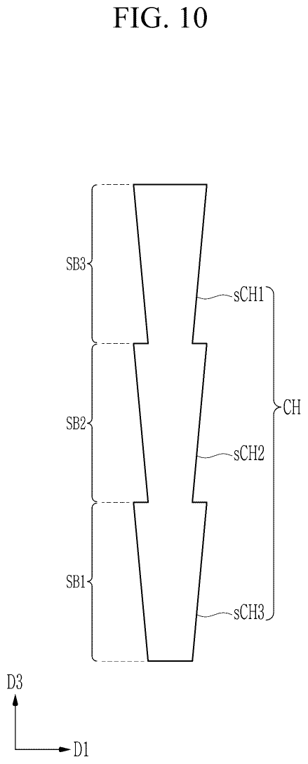

FIG. 8 is a perspective view illustrating the memory cell array of FIG. 4. FIG. 9 is a top plan view illustrating the memory cell array of FIG. 4. FIG. 10 is a cross-sectional view of a channel hole according to an embodiment.

Referring to FIG. 4, and FIGS. 8 to 10, the memory cell array 510 may include a plurality of memory blocks BLK1 to BLKz that extend along the first to third directions D1 to D3. Depending on the embodiment, the memory blocks BLK1 to BLKz may be selected by the row decoder 530. For example, the row decoder 530 may select a memory block BLK corresponding to a block address from the plurality of memory blocks BLK1 to BLKz. In accordance with an embodiment, the row decoder 530 may select at least one sub-block SBi within the memory block BLK in response to the row address X_ADDR.

Each of the plurality of memory blocks BLK1 to BLKz may include a plurality of channel holes CHs. Depending on the embodiment, the plurality of channel holes CHs may be disposed in the plurality of memory blocks BLK1 to BLKz while being spaced apart from each other in the first direction D1 or the second direction D2.

Each of the channel holes CH may extend in the third direction D3 extending perpendicular to the substrate. Each of the channel holes CH may correspond to a memory cell string NS, such as one of a plurality of memory cell strings NS11 to NS33.

The channel hole CH may include first to third sub-channel holes sCH1-sCH3 disposed along the third direction D3 from the substrate. According to embodiments, at least some of the first to third sub-channel holes sCH1 to sCH3 may be disposed to overlap each other in the third direction D3.

Since each of the first to third sub-channel holes sCH1 to sCH3 is formed by etching a portion of gate electrodes and insulating films stacked on the substrate, the etching may not be well accomplished as the depth from the top surface down toward the substrate increases. Accordingly, the diameters of the first to third sub-channel holes sCH1 to sCH3 may be smaller as the sub-channel holes are closer to the substrate.

Although not illustrated, a stopper layer may be disposed at the boundary between the sub-channel holes. For example, a stopper layer may be disposed at the boundary between the first and second sub-channel holes sCH1 and sCH2 and between the second and third sub-channel holes sCH2 and sCH3. According to an embodiment, the stopper layer may be a material layer disposed for stepwise formation of the sub-channel holes. The stopper layer may have a relatively high etch selectivity with respect to other layers of the block. The stopper layer may include a plurality of material layers having a multi-layer structure. According to an embodiment, the stopper layer may be formed of polysilicon and a memory cell disposed in the stopper layer may operate as an intermediate switch transistor. The memory cells in the stopper layer may be improper for storing data, and the stopper layer may be used as the boundary portion to form the intermediate switching transistors. A corresponding stopper layer may be formed between immediately adjacent sub-blocks of a block and such a stopper layer may not be formed elsewhere in the block (e.g., a stopper layer within a sub-block may not be formed).

Each of the first to third sub-channel holes sCH1 to sCH3 may correspond to a plurality of sub-blocks SB1, SB2, and SB3 in FIG. 5, respectively. In the first sub-channel hole sCH1 according to an embodiment, the memory cells connected to the first to fourth wordlines WL1, WL2, WL3, and WL4 in FIG. 5 may be formed. In the second sub-channel hole sCH2 according to an embodiment, the memory cells connected to the fifth to eighth wordlines WL5, WL6, WL7, and WL8 in FIG. 5 may be formed. In the third sub-channel hole sCH3 according to an embodiment, the memory cells connected to the ninth to twelfth wordlines WL9, WL10, WL11, and WL12 in FIG. 5 may be formed.

In FIG. 10, it is illustrated that the channel hole CH includes three sub-channel holes, but the number of sub-channel holes illustrated is for illustrative purposes only, and the technical ideas of the present disclosure are not limited thereto. Accordingly, the channel hole CH may include any number of sub-channel holes.

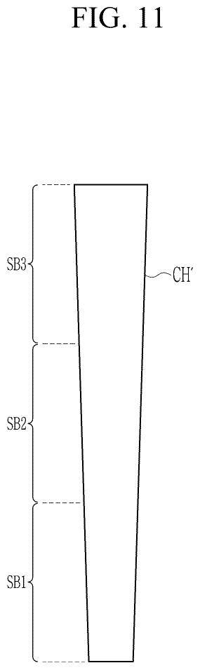

FIG. 11 is a cross-sectional view of a channel hole according to an embodiment. A channel hole CH′ of FIG. 11 may correspond to the channel hole CH of FIG. 10. For ease of description, the channel hole CH′ of FIG. 11 will be described with emphasis on differences from the channel hole CH of FIG. 10.

Referring to FIGS. 4, 8 to 9, and 11, the channel hole CH′ may be formed by etching a single channel hole, without stepwise formation of a plurality of sub-channel holes. Accordingly, the diameter of the channel hole CH′ may decrease as the channel hole CH′ is closer to the substrate. According to the embodiment, a stopper layer may not be disposed within the channel hole CH′.

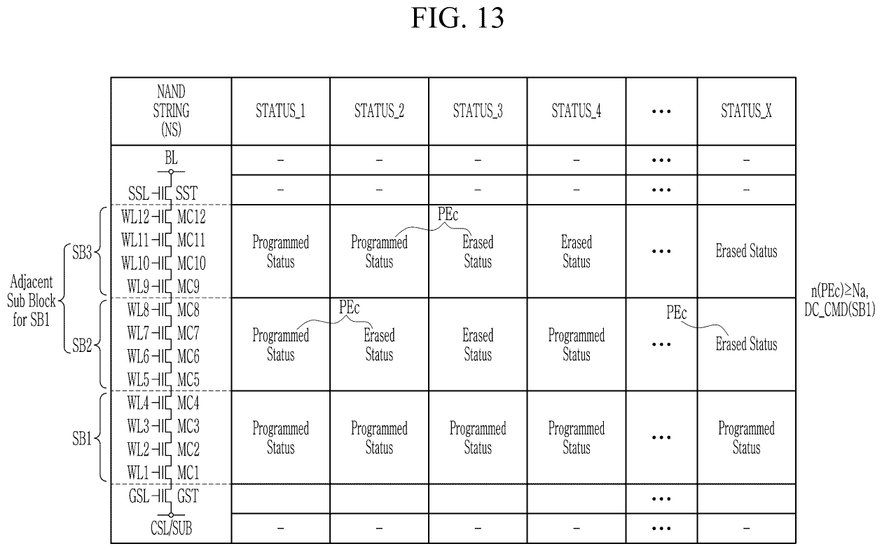

FIG. 12 is a flowchart illustrating a method of operating the storage device according to an embodiment. FIGS. 13 to 16 are diagrams illustrating the method of operating the storage device according to an embodiment.

Referring to FIGS. 2 to 7, and FIG. 12, the storage controller 40 can log a command for an adjacent sub-block to monitor the disturb circumstance for the sub-block (S110).

The storage controller 40 may log a command CMD for an adjacent sub-block of a particular sub-block to monitor the disturb circumstance of the particular sub-block. For example, the storage controller 40 may log program/erase cycles for an adjacent sub-block, or log read a command for wordlines within an adjacent sub-block.

In the present disclosure, an adjacent sub-block may be a sub-block that is connected to the same bitline BL as the sub-block that is the subject of the monitor operation, and may be separated from the monitored sub-block by a plurality of wordlines stacked into a single stacked structure. Thus, the adjacent sub-block need not be immediately adjacent (i.e., with need no additional sub-block positioned therebetween) to the monitored sub-block.

In describing the memory block BLKi in FIG. 5 as an example, the sub-block disturb check module DCM of the storage controller 40 may log commands CMDs for the second and third sub-blocks SB2 and SB3 provided to the non-volatile memory device 50 to monitor the disturb circumstance of the first sub-block SB1.

The storage controller 40 checks the disturb circumstance for the sub-block (S120).

The storage controller 40 may check the disturb circumstance for the sub-block based on the logged command CMD.

FIG. 13 is a diagram illustrating an example of a disturb circumstance for the first sub-block SB1. Referring further to FIG. 13, the memory block BLKi including the first to third sub-blocks SB1 to SB3 may be operated upon receiving commands CMDs from the storage controller 40 to have first to X^{th} block status STATUS_1 to STATUS_X in chronological order.

In the first block status STATUS_1, the first to third sub-blocks SB1 to SB3 may be in the programmed status. Subsequently, the non-volatile memory device 50 may receive an erase command for the second sub-block SB2 from the storage controller 40.

As the storage controller 40 provides the erase command to the non-volatile memory device 50, the sub-block disturb check module DCM may log program/erase cycles PEc for the second sub-block SB2 to monitor the disturb circumstance for the first sub-block SB1.

By the operation of the non-volatile memory device 50 in response to the erase command for the second sub-block SB2, in the second block status STATUS_2, the second sub-block SB2 may be in the erased status and the first and third sub-blocks SB1 and SB3 may be in the programmed status.

Subsequently, the non-volatile memory device 50 may receive an erase command for the third sub-block SB3 from the storage controller 40.

As the storage controller 40 provides the erase command to the non-volatile memory device 50, the sub-block disturb check module DCM may log the program/erase cycle PEc for the third sub-block SB3 to monitor the disturb circumstance for the first sub-block SB1.

By the operation of the non-volatile memory device 50 in response to the erase command for the third sub-block SB3, in the third block status STATUS_3, the second and third sub-blocks SB2 and SB3 may be in the erased status and the first sub-block SB1 may be in the programmed status.

Subsequently, the non-volatile memory device 50 may receive a program command for the second sub-block SB2 from the storage controller 40.

By the operation of the non-volatile memory device 50 in response to the provision of the program command for the second sub-block SB2, in the fourth block status STATUS_4, the third sub-block SB3 may be in the erased status and the first and second sub-blocks SB1 and SB2 may be in the programmed status.

As the storage controller 40 provides the non-volatile memory device 50 with the erase command for the second sub-block SB2 before the X^{th} block status STATUS_X, the sub-block disturb check module DCM may monitor the disturb circumstance for the first sub-block SB1 by logging the program/erase cycle PEc for the second sub-block SB2.

By the operation of the non-volatile memory device 50 according to the provision of the erase command to the second sub-block SB2, the X^{th} block status STATUS_X, the second and third sub-blocks SB2 and SB3 may be in the erased status and the first sub-block SB1 may be in the programmed status.

In accordance with an embodiment, the first sub-block SB1 may remain in the programmed status as the memory block BLKi changes from the first to the X^{th} block status STATUS_1 to STATUS_X. Depending on the embodiment, the first sub-block SB1 may be floated while the erase operation is performed on the adjacent second and third sub-blocks SB2 and SB3. If the first sub-block SB1 changes from the programmed status to the erased status, the log information logged to monitor the disturb circumstance of the first sub-block SB1 may be cleared and a new log operation to monitor the disturb circumstance may be performed.

Although FIG. 13 illustrates that the first sub-block SB1 maintains the programmed status during the first to X^{th} block statuses STATUS_1 to STATUS_X of the memory block BLKi, the present disclosure is not limited thereto, and the first sub-block SB1 may maintain the erased status during the first to X^{th} block statuses STATUS_1 to STATUS_X depending on the embodiment.

In accordance with an embodiment, the sub-block disturb check module DCM may compare the number of occurrences of the program/erase cycles PEc for the adjacent sub-block logged during the first to X^{th} block statuses STATUS_1 to STATUS_X and a first reference value Na, which is a predetermined value. According to the embodiment, when the number of occurrences of the program/erase cycles PEc for the logged adjacent sub-block is equal to or greater than the first reference value Na, the sub-block disturb check module DCM may provide the non-volatile memory device 50 with the disturb check command DC_CMD for the first sub-block SB1.

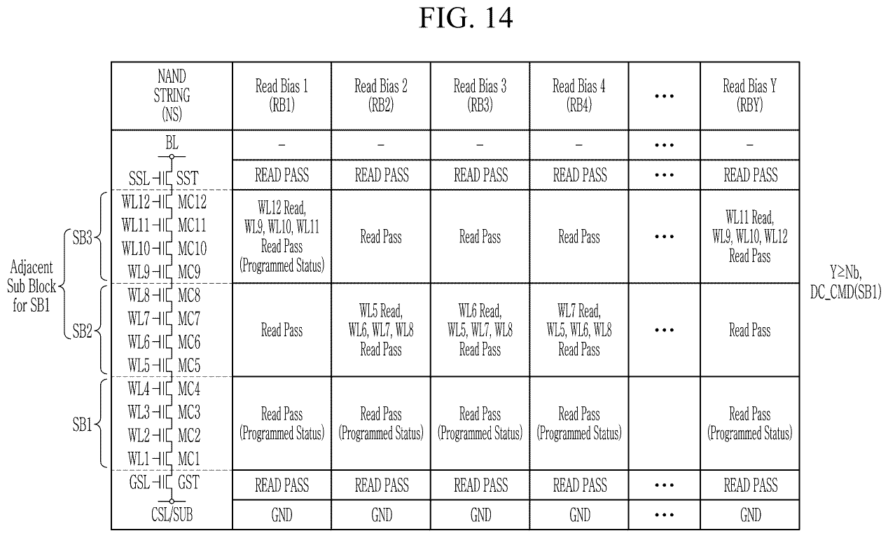

FIG. 14 is a diagram illustrating an example of the disturb circumstance for the first sub-block SB1. Referring further to FIG. 14, the memory block BLKi including the first to third sub-blocks SB1 to SB3 may be operated by receiving the command CMD from the storage controller 40 such that first to Y^{th} read biases RB1 to RBY are applied in chronological order.

The storage controller 40 may provide the non-volatile memory device 50 with a read command for the memory cell connected to the twelfth wordline WL12 in the third sub-block SB3. The storage controller 40 may monitor the disturb circumstance to the first sub-block SB1 while logging the read command for the twelfth wordline WL12 in the third sub-block SB3. According to the read command, a first read bias RB1 may be applied to the memory block BLKi.

In the first read bias RB1, the string select line SSL, the ground select line (GSL), and the first to eleventh wordlines WL1 to WL11 may be provided with a read pass voltage, the common source line CSL may be provided with a ground voltage, and the twelfth wordline WL12 may be provided with a read voltage Vrd.

The storage controller 40 may then provide the non-volatile memory device 50 with the read command for the memory cell connected to the fifth wordline WL5 in the second sub-block SB2. The storage controller 40 may monitor the disturb circumstance of the first sub-block SB1 while logging the read command for the fifth wordline WL5 in the second sub-block SB2. According to the read command, a second read bias RB2 may be applied to the memory block BLKi.

In the second read bias RB2, the string select line SSL, the ground select line GSL, the first to fourth wordlines WL1 to WL4, and the sixth to twelfth wordlines WL6 to WL12 may be provided with a read pass voltage, the common source line CSL may be provided with a ground voltage, and the fifth wordline WL5 may be provided with a read voltage Vrd.

The storage controller 40 may then provide the non-volatile memory device 50 with the read command for the memory cell connected to the sixth wordline WL6 in the second sub-block SB2. The storage controller 40 may monitor the disturb circumstance of the first sub-block SB1 while logging the read command for the sixth wordline WL6 in the second sub-block SB2. According to the read command, a third read bias RB3 may be applied to the memory block BLKi.

In the third read bias RB3, the string select line SSL, the ground select line GSL, the first to fifth wordlines WL1 to WL5, and the seventh to twelfth wordlines WL7 to WL12 may be provided with read pass voltages, the common source line CSL may be provided with a ground voltage, and the sixth wordline WL6 may be provided with a read voltage Vrd.

The storage controller 40 may then provide the non-volatile memory device 50 with a read command for the memory cell connected to the seventh wordline WL7 in the second sub-block SB2. The storage controller 40 may monitor the disturb circumstance of the first sub-block SB1 while logging the read command for the seventh wordline WL7 in the second sub-block SB2. According to the read command, a fourth read bias RB4 may be applied to the memory block BLKi.

In the fourth read bias RB4, the string select line SSL, the ground select line GSL, the first to sixth wordlines WL1 to WL6, and the eighth to twelfth wordlines WL8 to WL12 may be provided with a read pass voltage, the common source line CSL may be provided with a ground voltage, and the seventh wordline WL7 may be provided with a read voltage Vrd.

The storage controller 40 may then provide the non-volatile memory device 50 with a read command for the memory cell connected to the eleventh wordline WL11 in the third sub-block SB3. The storage controller 40 may monitor the disturb circumstance of the third sub-block SB3 while logging the read command for the eleventh wordline WL11 in the third sub-block SB3. According to the read command, Y^{th} read bias RBY may be applied to the memory block BLKi.

In the Y^{th} read bias RBY, the string select line SSL, the ground select line GSL, the first to tenth wordlines WL1 to WL10, and the twelfth wordline WL12 may be provided with a read pass voltage, the common source line CSL may be provided with a ground voltage, and the eleventh wordline WL11 may be provided with a read voltage Vrd.

According to an embodiment, the first sub-block SB1 may remain in the programmed status while the first to Y^{th} read biases RB1 to RBY are applied to the memory block BLKi. If the first sub-block SB1 changes from the programmed status to the erased status during the application of the first to Yth read biases RB1 to RBY, the log information logged to monitor the disturb circumstance of the first sub-block SB1 in the programmed status may be cleared, and a new log operation may be performed to monitor the disturb circumstance of the first sub-block SB1.

Although FIG. 14 illustrates that the first sub-block SB1 maintains the programmed status during the application of the first to Y^{th} read biases RB1 to RBY of the memory block BLKi, the present disclosure is not limited thereto, and the first sub-block SB1 may be maintained in the erased status during the application of the first to Y^{th} read biases RB1 to RBY according to some embodiments.

In accordance with an embodiment, the sub-block disturb check module DCM may compare Y, the number of occurrences of the read bias application to adjacent sub-blocks logged during the application of the first to Yth read biases RB1 to RBY, to a second reference value Nb, which is a predetermined value. In accordance with an embodiment, when the number of occurrences of the read biases for the wordlines within the logged adjacent sub-block is equal to or greater than the second reference value Nb, the sub-block disturb check module DCM may provide the non-volatile memory device 50 with a disturb check command DC_CMD for the first sub-block SB1.

Referring again to FIG. 12, when a disturb circumstance for the sub-block does not occur, the storage controller 40 may repeat the log operation of operation S110.

When the storage controller 40 determines that the disturb circumstance has occurred for the sub-block, the storage controller 40 provides the disturb check command DC_CMD to the non-volatile memory device 50 (S130).

The non-volatile memory device 50, upon receipt of the disturb check command DC_CMD, performs a disturb check operation on the wordline within the sub-block to generate disturb information DI for the sub-block (S140).

The non-volatile memory device 50 may, in response to receiving the disturb check command DC_CMD for the first sub-block SB1, perform a disturb check operation on the first wordline WL1 in the first sub-block SB1.

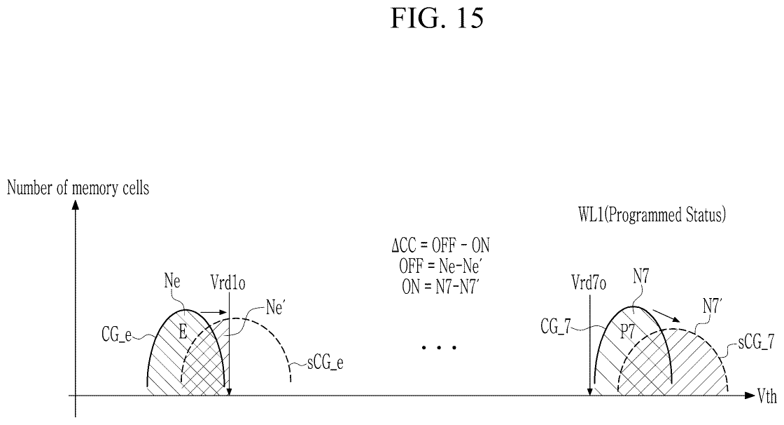

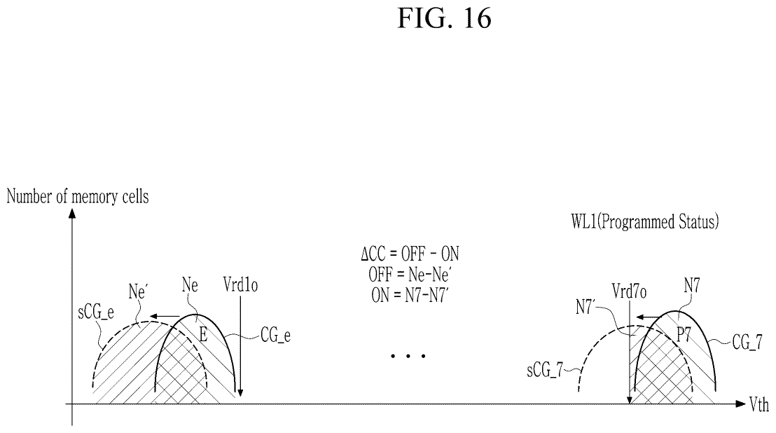

FIGS. 15 and 16 are diagrams illustrating a disturb check operation performed on a single wordline. Referring further to FIGS. 15 and 16, the distribution of the threshold voltage for the cell groups CG_e to CG_7 in the first wordline WL1 may be shifted to the distribution of the threshold voltage for the distribution-shifted cell groups sCG_e to sCG_7, e.g. through disturb due to the operation of the adjacent sub-blocks SB2 and SB3. For ease of description hereinafter, the disturb check operation will be described on the premise of the distribution shift of the threshold voltage. Depending on the embodiment, the disturb check operation may be an operation to check the distribution shift of the threshold voltage for the memory cells in the sub-block.

Furthermore, in FIGS. 15 and 16, a disturb check operation for the first sub-block SB1 is performed based on the first wordline WL1, but the disturb check operation may be performed based on other wordlines within the first sub-block SB1 according to embodiments.

The disturb check circuit 521 may count the on-cell determined memory cells based on the first initial read voltage Vrd10 prior to receipt of the disturb check command DC_CMD to calculate a first erase cell count Ne, which is the number of memory cells in the erased status E.

After receiving the disturb check command DC_CMD, the disturb check circuit 521 may count the memory cells determined to be on-cells in the distribution shift erase cell group sCG_e based on the first initial read voltage Vrd1o to calculate a second erase cell count Ne′.

In accordance with an embodiment, the disturb check circuit 521 may calculate a change value of the on-cell determined memory cells based on the first erase cell count Ne and the second erase cell count Ne′ to generate an off-cell count OFF. According to an embodiment, the disturb check circuit 521 may subtract the second erased cell count Ne′ from the first erased cell count Ne to generate the off-cell count OFF.

The disturb check circuit 521 may count the memory cells determined to be off-cells based on the seventh initial read voltage Vrd70 prior to receipt of the disturb check command DC_CMD to calculate a first cell count N7, which is the number of memory cells in the seventh status P7.

After receiving the disturb check command DC_CMD, the disturb check circuit 521 may count the memory cells that are determined to be off-cells in the seventh distribution-shifted cell group sCG_7 based on the seventh initial read voltage Vrd7o to calculate a second cell count N7′.

In accordance with an embodiment, the disturb check circuit 521 may calculate a change value of the memory cells determined to be off-cells based on the first cell count N7 and the second cell count N7′ to generate an on-cell count ON. In accordance with an embodiment, the disturb check circuit 521 may subtract the second cell count N7′ from the first cell count N7 to generate the on-cell count ON.

The disturb check circuit 521 may calculate a cell count change value ΔCC based on the off-cell count OFF and the on-cell count ON. In accordance with an embodiment, the disturb check circuit 521 may subtract the on-cell count ON from the off-cell count OFF to generate the cell count change value ΔCC.

Based on the calculated cell count change value ΔCC and the operating condition table OT, the disturb check circuit 521 may generate disturb information DI corresponding to the calculated cell count change value ΔCC.

In accordance with an embodiment, the disturb information DI corresponding to the relatively low cell count change value ΔCC may imply a distribution decrease of the threshold voltage for the memory cell in the first sub-block SB1. In accordance with an embodiment, the disturb information DI corresponding to a relatively high cell count change value ΔCC may imply a distribution increase in the threshold voltage for the memory cell in the first sub-block SB1.

Referring to FIG. 7 for illustrative purposes, a zero index INDEXo, corresponding to a cell count change value ΔCC of zero, may imply that there is no change in the distribution of the threshold voltage for the memory cell compared to the initial programmed status or the initial erased status. The disturb information DI corresponding to the cell count change value ΔCC lower than zero may imply a decrease (e.g., a downward shift) in the distribution of the threshold voltage for the memory cell compared to the initial programmed status or the initial erased status. In accordance with an embodiment, the disturb information DI corresponding to an index close to the first index INDEX1 may imply a relatively large decrease in the distribution of the threshold voltage for the memory cell. The disturb information DI corresponding to a cell count change value ΔCC greater than zero may imply that the distribution of the threshold voltage for the memory cell increases (e.g., shifts upwards) compared to the initial programmed status or the initial erased status. In accordance with an embodiment, the disturb information DI corresponding to an index close to the n^{th} index INDEXn may imply a relatively large increase in the distribution of the threshold voltage for the memory cell. In some embodiments, the system may use such information (e.g., the disturb information DI, the cell count change values ΔCC, and/or the shifts in the distribution of the threshold voltage) to determine whether disturb has occurred.

The disturb check operation of operation S140 according to an embodiment may be performed based on an off-cell count for the erased status E, which is the lowest status in one wordline, and an on-cell count for the seventh status P7, which is the highest state, to generate disturb information DI implying the distribution shift of the threshold voltage within the sub-block with relative ease. In the disturb check operation of operation S140 according to the embodiment, a threshold voltage check operation for all memory cells in the sub-block is not required.

Referring again to FIG. 12, the disruption check circuit 521 provides the disruption information DI to the memory cell array 510, and the memory cell array 510 stores the disturb information DI (S150).

In accordance with an embodiment, the memory cell array 510 may store the disturb information DI provided by the control logic 520.

In accordance with an embodiment, the memory cell array 510 may store the disturb information DI in the memory block where training data for configurations of the non-volatile memory device 50, log information from the storage device 30, and the like are stored.

The control logic 520 performs the operation on the sub-block based on the operational condition corresponding to the stored disturb information DI (S160).

Based on the operating condition table OT (for example, the operating condition table OTa of FIG. 7) and the stored disturb information DI, the control logic 520 may perform the read operation, the erase operation, or the program operation on the sub-block with the operating condition corresponding to the disturb information DI.

In accordance with an embodiment, the control logic 520 may perform the read operation, the erase operation, or the program operation on the sub-block based on the operating voltage corresponding to the disturb information DI.

In accordance with an embodiment, the control logic 520 may perform the read operation, the erase operation, or the program operation on the sub-block based on an operating time corresponding to the disturb information DI.

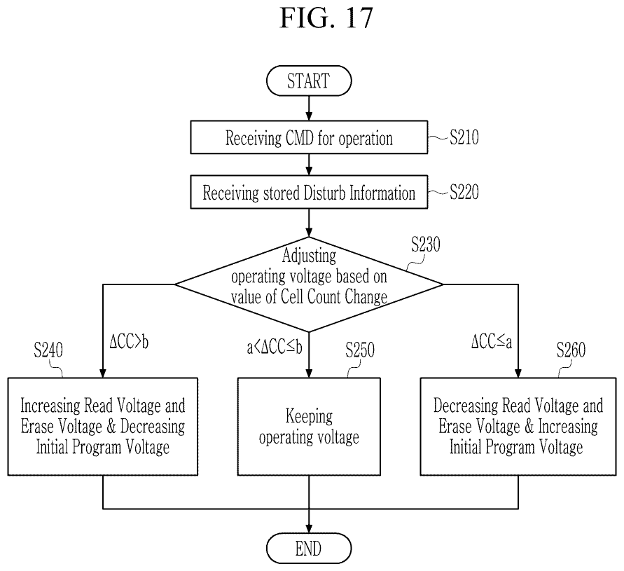

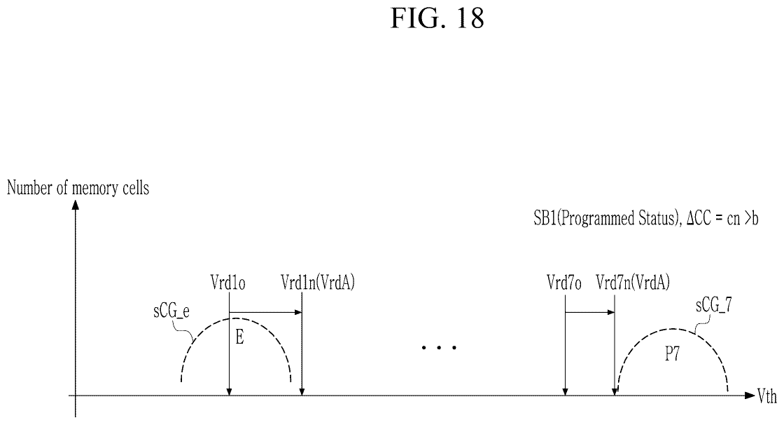

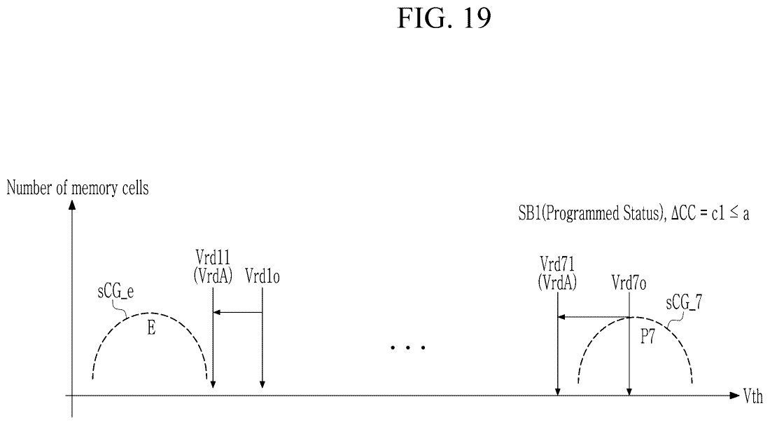

FIG. 17 is a flowchart illustrating a method of operating the storage device according to an embodiment. FIGS. 18 and 19 are diagrams illustrating the method of operating the storage device according to an embodiment.

In some embodiments, operation S210 to operation S260 of FIG. 17 may be included in operation S160 of FIG. 12.

Referring to FIGS. 2 to 7, and FIG. 17, the non-volatile memory device 50 receives a command CMD of an operation for the sub-block (S210).

The non-volatile memory device 50 may receive a command CMD of a read operation, an erase operation, or a program operation for the sub-block from the storage controller 40.

Referring to FIG. 5 for illustrative purposes, the non-volatile memory device 50 may receive a read command for one page in the first sub-block SB1 from the storage controller 40.

The control logic 520, upon receiving the command CMD of the operation for the sub-block, receives the stored disturb information DI (S220).

In response to receiving the command CMD of the read operation, the erase operation, or the program operation for the sub-block from the storage controller 40, the control logic 520 may receive the disturb information DI stored in the memory cell array 510.

Referring to FIG. 5 for illustrative purposes, in response to the receipt, by the non-volatile memory device 50, of the read command for the first sub-block SB1 from the storage controller 40, the control logic 520 may receive the disturb information DI for the first sub-block SB1 stored in the memory cell array 510.

The control logic 520 adjusts an operating conditions OCa for the sub-block based on the cell count change value ΔCC corresponding to the disturb information DI (S230).

For example, the control logic 520 may receive an index stored as the disturb information DI for the sub-block, and adjust the operating conditions to operating voltages for the sub-block corresponding to the received index in the operating condition table OTa (e.g., as shown in FIG. 7). Subsequent operations for the sub-block may thus be performed in accordance with the new operating conditions corresponding to the received index.

When the cell count change value ΔCC corresponding to the disturb information DI is greater than a predetermined second boundary value b, the control logic 520 adjusts the operating voltage by increasing the read voltage Vrd and the erase voltage Vers, and decreasing the first program voltage Vpini (S240).

If the cell count change value ΔCC corresponding to the disturb information DI is greater than the predetermined second boundary value b, it may imply that the distribution of the threshold voltage for the memory cell in the sub-block is increased compared to the initial programmed status or the initial erased status. In accordance with an embodiment, the second boundary value b may be a positive integer.

FIG. 18 is a diagram illustrating an operation in which the read voltage Vrd is adjusted when the cell count change value ΔCC corresponding to the disturb information DI is the n^{th} cell count change value cn.

Referring further to FIG. 18, the control logic 520 may receive disturb information DI for the first sub-block SB1, and the cell count change value ΔCC corresponding to the received disturb information DI may be the nth cell count change value cn. In accordance with an embodiment, the n^{th} cell count change value cn may be a positive integer that is higher than the second boundary value b.

The control logic 520 may adjust the read voltage Vrd by increasing the read voltages from the first to seventh initial read voltages Vrd1o to Vrd7o to the first_n to seventh_n read voltages Vrd1n to Vrd7n based on the cell count change value ΔCC corresponding to the disturb information DI. In accordance with an embodiment, the control logic 520 may adjust the first_n to seventh_n read voltages Vrd1n to Vrd7n and may control the voltage generator 550 such that a read operation is performed based on the adjusted read voltage Vrd1n to Vrd7n. As will be appreciated, several read voltages are used in a read operation to detect the different data states of the memory cells (e.g., to determine which one of eight (8) data states a memory cell may be programmed to in a TLC memory cell).

The non-volatile memory device 50 may divide the memory cells in the first sub-block SB1 into distribution-shifted cell groups sCG_e to sCG_7 based on the first_n to seventh_n read voltages Vrd1n to Vrd7n, and may read the data stored in the memory cells in the first sub-block SB1. By the adjustment operation of increasing the read voltage Vrd as described above, the memory cell in the first sub-block SB1 may perform a read operation reflecting that the threshold voltage is increased by the disturb, and data errors occurring in the read operation may be prevented.

Referring again to FIG. 17, in an exemplary case where the cell count change value ΔCC corresponding to the received disturb information DI is the n^{th} cell count change value cn, the control logic 520 may adjust the erase voltage Vers by increasing the voltage from the initial erase voltage Verso to the n^{th} erase voltage Versn based on the n^{th} cell count change value cn. In accordance with an embodiment, the control logic 520 may adjust the n^{th} erase voltage Versn to an adjusted erase voltage, and may control the voltage generator 550 such that an erase operation is performed based on the adjusted erase voltage.

Referring again to FIG. 17, in an exemplary case where the cell count change value ΔCC corresponding to the received disturb information DI is the n^{th} cell count change value cn, the control logic 520 may adjust the first program voltage Vpini by decreasing the program voltage from the initial first program voltage Vpinio to the n^{th} first program voltage Vpinin based on the nth cell count change value cn. In accordance with an embodiment, the control logic 520 may adjust the n^{th} first program voltage Vpinin to the adjusted first program voltage and control the voltage generator 550 such that program operation is performed based on the adjusted first program voltage.

By adjusting the operating voltage in operation S240, the non-volatile memory device 50 may perform the operation on the sub-block by reflecting that the threshold voltage has been increased by the disturb of the memory cell in the sub-block, and may prevent data errors caused by the increase in the threshold voltage.

When the cell count change value ΔCC corresponding to the disturb information DI is equal to or less than the predetermined second boundary value b and is greater than the predetermined first boundary value a, the control logic 520 adjusts the operating voltage by maintaining the read voltage Vrd, the erase voltage Vers, and the first program voltage Vpini (S250).

When the cell count change value ΔCC corresponding to the disturb information DI is equal to or less than the predetermined second boundary value b and is greater than the predetermined first boundary value a, it may imply that the distribution of threshold voltages for the memory cell in the sub-block is maintained in the initial programmed status or initial erased status. In accordance with an embodiment, the first boundary value a may be a negative integer and the second boundary value b may be a positive integer.

The control logic 520 may receive the disturb information DI for the first sub-block SB1, and the cell count change value ΔCC corresponding to the received disturb information DI may be zero. In accordance with an embodiment, the first boundary value a may be a negative integer and the second boundary value b may be a positive integer.

The control logic 520 may adjust the read voltage Vrd by maintaining the first to seventh initial read voltages Vrd1o to Vrd7o, based on the feature that the cell count change value ΔCC corresponding to the disturb information DI is zero. In accordance with an embodiment, the control logic 520 may adjust the first to seventh initial read voltages Vrd1o to Vrd7o to the adjusted read voltage, and may control the voltage generator 550 such that the read operation is performed based on the adjusted read voltage.

The control logic 520 may adjust the erase voltage Vers by maintaining the initial erase voltage Verso based on the feature that the cell count change value ΔCC corresponding to the disturb information DI is zero. In accordance with an embodiment, the control logic 520 may adjust the initial erase voltage Verso to the adjusted erase voltage and control the voltage generator 550 such that the erase operation is performed based on the adjusted erase voltage.

The control logic 520 may adjust the first program voltage Vpini by maintaining the initial first program voltage Vpinio, based on the feature that the cell count change value ΔCC corresponding to the disturb information DI is zero.

In accordance with an embodiment, the control logic 520 may adjust the initial first program voltage Vpinio to the adjusted first program voltage and control the voltage generator 550 such that program operation is performed based on the adjusted first program voltage.

By adjusting the operating voltage in operation S250, the non-volatile memory device 50 may perform the operation on the sub-block by reflecting that the threshold voltage of the memory cell in the sub-block is maintained.

When the cell count change value ΔCC corresponding to the disturb information DI is equal to or less than the predetermined first boundary value a, the control logic 520 adjusts the operating voltage by decreasing the read voltage Vrd and the erase voltage Vers, and increasing the first program voltage Vpini (S260).

When the cell count change value ΔCC corresponding to the disturb information DI is greater than the predetermined first boundary value a, it may imply that the distribution of the threshold voltage for the memory cell in the sub-block is decreased compared to the initial programmed status or the initial erased status. In accordance with an embodiment, the first boundary value a may be a negative integer.

FIG. 19 is a diagram illustrating an operation in which the read voltage Vrd is adjusted when the cell count change value ΔCC corresponding to the disturb information DI is the first cell count change value c1.

Referring further to FIG. 19, the control logic 520 may receive the disturb information DI for the first sub-block SB1, and the cell count change value ΔCC corresponding to the received disturb information DI may be the first cell count change value c1. In accordance with an embodiment, the n^{th} cell count change value c1 may be a negative integer that is lower than the first boundary value a.

The control logic 520 may adjust the read voltage Vrd by decreasing the read voltages from the first to seventh initial read voltages Vrd1o to Vrd7o to the first_1 to seventh_1 read voltages Vrd11 to Vrd71 based on the cell count change value ΔCC corresponding to the disturb information DI. In accordance with an embodiment, the control logic 520 may adjust the read voltages to the first_1 to seventh_1 read voltages Vrd11 to Vrd71 and may control the voltage generator 550 such that the read operation is performed based on the adjusted read voltages (first_1 to seventh_1 read voltages Vrd11 to Vrd71).

The non-volatile memory device 50 may divide the memory cells in the first sub-block SB1 into distribution-shifted cell groups sCG_e to sCG_7 based on the first_1 to seventh_1 read voltages Vrd11 to Vrd71, and may read the data stored in the memory cells in the first sub-block SB1. By the adjustment operation of decreasing the read voltage Vrd as described above, the memory cell in the first sub-block SB1 may perform the read operation by reflecting that the threshold voltage is decreased by the disturb, and data errors occurring in the read operation may be prevented.

Referring again to FIG. 17, in an exemplary case where the cell count change value ΔCC corresponding to the received disturb information DI is the first cell count change value c1, the control logic 520 may adjust the erase voltage Vers by decreasing the erase voltage from the initial erase voltage Verso to the first erase voltage Vers1 based on the first cell count change value c1. In accordance with an embodiment, the control logic 520 may adjust the first erase voltage Vers1 to the adjusted erase voltage, and may control the voltage generator 550 such that the erase operation is performed based on the adjusted erase voltage.

In accordance with an embodiment, in an exemplary case where the cell count change value ΔCC corresponding to the received disturb information DI is the first cell count change value c1, the control logic 520 may adjust the first program voltage Vpini by increasing the initial first program voltage Vpinio to the first first program voltage Vpini1 based on the first cell count change value c1. Depending on the embodiment, the control logic 520 may adjust the first first program voltage Vpini1 to the adjusted first program voltage and control the voltage generator 550 such that the program operation is performed based on the adjusted first program voltage.

By adjusting the operating voltage in operation S260, the non-volatile memory device 50 may perform the operation on the sub-block by reflecting that the threshold voltage has been decreased by the disturb, and prevent data errors caused by the decrease of the threshold voltage.

The non-volatile memory device 50 may perform the operation by adjusting the operating conditions OCa based on the disturb information DI by operating as in operations S210 to S260 above. By adjusting the operating conditions OCa based on the disturb information DI, the non-volatile memory device 50 may perform the operation on the sub-block reflecting the distribution shift of the threshold voltage varied by the operation of the adjacent sub-block, and may improve the reliability of the operation.

In accordance with an embodiment, the non-volatile memory device 50 may perform the operation by reflecting the distribution shift of the threshold voltage due to the disturb to reduce the occurrence of uncorrectable errors, and may reduce the number of occurrences of the operations of the read reclaim, thereby improving performance and reliability. Due to the reduction in the number of occurrences of the read reclamation operation, the storage device 30 is able to perform operations responsive to the request of the host 20 while improving the delay due to read reclaim.

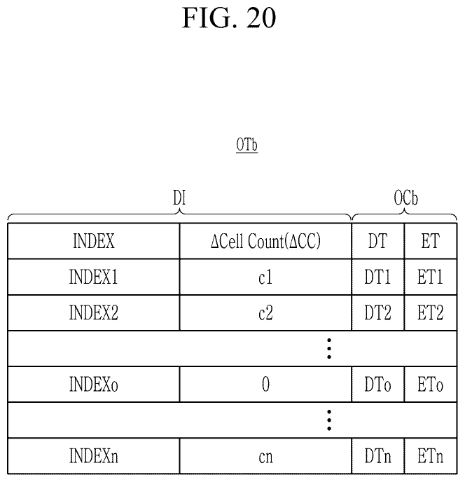

FIG. 20 is a diagram illustrating an operational condition table according to an embodiment. The operational condition table OTb of FIG. 20 may correspond to the operational condition table OTa of FIG. 7. For ease of description, the operating condition table OTb of FIG. 20 will be described in detail with emphasis on differences from the operating condition table OTa of FIG. 7.

Referring to FIGS. 2 to 6, and FIG. 20, the operating condition table OTb according to the embodiment may include operating condition information including disturb information DI, and an operating time OCb corresponding to the disturb information DI. The operating time OCb may include a develop time DT, and an erase time ET.

According to embodiments, the operating condition table OTb may include first to n^{th} indexes INDEX1 to INDEXn that represent the disturb information DI, and first to n^{th} cell count change values c1 to cn that represent the cell count change values (ΔCC) corresponding to the first to n^{th} indexes INDEX1 to INDEXn, respectively. In accordance with an embodiment, the operating condition table OTb may include the cell count change value ΔCC itself as disturb information DI.

According to an embodiment, the cell count change value ΔCC may be an integer including zero, a negative integer, or a positive integer. According to an embodiment, the first to n^{th} cell count change values c1 to cn corresponding to the first to n^{th} indices INDEX1 to INDEXn may sequentially increase in value. According to an embodiment, closer to the first index INDEX1 may imply a distribution decrease in the threshold voltage for the memory cells in the sub-block SBi, and closer to the n^{th} index INDEXn may imply a distribution increase in the threshold voltage for the memory cells in the sub-block SBi. The first to n^{th} indexes INDEX1 to INDEXn may include a zero index INDEXo corresponding to a cell count change value ΔCC of zero.

According to embodiments, the development time DT may be a time interval during a development period during which the precharge voltage on the bitline BL is varied to a sensing voltage to read the data stored in the memory cell. Depending on the embodiment, the erase time ET may be the time at which the erase voltage Vers is applied through the bitline BL or the common source line CSL to erase the data stored in the memory cell.

Referring to FIG. 20 for illustrative purposes, the operating condition table OTb may include operating condition information including a first index INDEX1, a first cell count change value c1, a first development time DT1 corresponding to the first index INDEX1, and a first erase time ET1.

The operating condition table OTb may include operating condition information including a second index INDEX2, a second cell count change value c2, a second development time DT2 corresponding to the second index INDEX2, and a second erase time ET2.

For example, the operating condition table OTb may include operating condition information including a zero index INDEXo, 0, an initial development time DTo corresponding to the zero index INDEXo, and an initial erase time ETo. In accordance with an embodiment, the operating time OCb corresponding to the zero index INDEXo may be equal to the operating time of the read operation and the erase operation prior to the adjustment by the disturb check circuit 521.

For example, the operating condition table OTb may include operating condition information including an n^{th} index INDEXn, an n^{th} cell count change value cn, and an n^{th} development time DTn corresponding to the nth index INDEXn, and an n^{th} erase time ETn.

Depending on the embodiment, the development time DT corresponding to an index closer to the first index INDEX1 may be shorter. For example, the first deployment time may be shorter than the second deployment time DT2.

Depending on the embodiment, the erase time ET corresponding to an index closer to the first index INDEX1 may be shorter. For example, the first erase time ET1 may be shorter than the second erase time ET2.

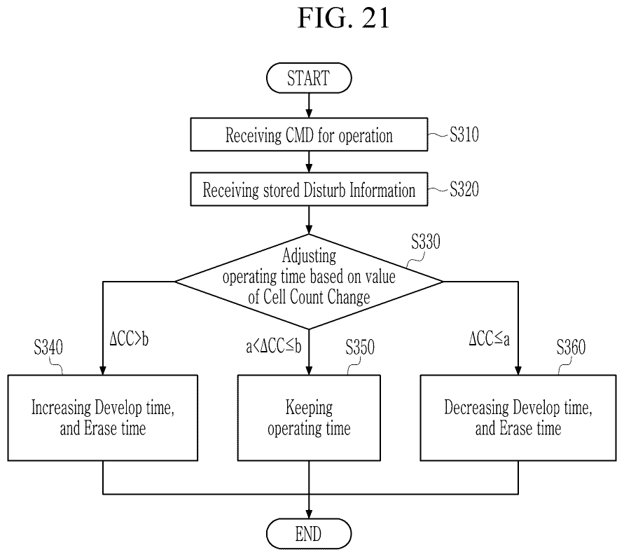

FIG. 21 is a flowchart illustrating a method of operating a storage device according to an embodiment. Each of operations S310 to S360 of FIG. 21 may correspond to operations S210 to S260 of FIG. 17, respectively. For ease of description, operations S310 to S360 of FIG. 21 will be described in detail with particular emphasis on the differences from operations S210 to S260 of FIG. 17. Depending on the embodiment, operations S310 to S360 of FIG. 21 may be included in operation S160 of FIG. 12.

Referring to FIGS. 2 to 6, and FIGS. 20 and 21, the description of operations S310 and S320 may be substituted with the description of operations S210 and S220 of FIG. 17.

The control logic 520 adjusts the operating time OCb for the sub-block based on the cell count change value ΔCC corresponding to the disturb information DI (S330).

For example, the control logic 520 may receive an index stored as the disturb information DI for a sub-block, and adjust the operating condition to an operating time for the sub-block corresponding to the received index in the operating condition table OTb.

When the cell count change value ΔCC corresponding to the disturb information DI is greater than the predetermined second boundary value b, the control logic 520 adjusts the operating time by increasing the development time DT and the erase time ET (S340).

When the cell count change value ΔCC corresponding to the disturb information DI is greater than the predetermined second boundary value b, it may imply that the distribution of the threshold voltage for the memory cell in the sub-block is increased compared to the initial programmed status or the initial erased status. In accordance with an embodiment, the second boundary value b may be a positive integer.

In accordance with an embodiment, in the exemplary case where the cell count change value ΔCC corresponding to the received disturb information DI is the n^{th} cell count change value cn, the control logic may adjust the development time DT by increasing the development time from the initial development time DTo to an n^{th} development time DTn. In accordance with an embodiment, the control logic 520 may adjust the n^{th} development time DTn to the adjusted development time, and may control the page buffer circuit 540 such that the read operation is performed based on the adjusted development time.

According to the embodiment, in the exemplary case where the cell count change value ΔCC corresponding to the received disturb information DI is the n^{th} cell count change value cn, the control logic 520 may adjust the erase time ET by increasing the erase time from the initial erase time ETo to the nth erase time ETn based on the n^{th} cell count change value cn. In accordance with an embodiment, the control logic 520 may adjust the n^{th} erase time ETn to the adjusted erase time and control the page buffer circuit 540 and the voltage generator 550 such that the erase operation is performed based on the adjusted erase time.

By adjusting the operating time in operation S340, the non-volatile memory device 50 may perform the operation on the sub-block by reflecting that the threshold voltage of the memory cell in the sub-block has been increased by the disturb, and may prevent data errors occurring by the increase of the threshold voltage.

When the cell count change value ΔCC corresponding to the disturb information DI is equal to or less than the predetermined second boundary value b and is greater than the predetermined first boundary value a, the control logic 520 adjusts the operating time by maintaining the development time DT and the erase time ET (S350).

When the cell count change value ΔCC corresponding to the disturb information DI is equal to or less than the predetermined second boundary value b and is greater than the predetermined first boundary value a, it may imply that the distribution of threshold voltages for the memory cell in the sub-block is maintained in the initial programmed status or initial erased status. In accordance with an embodiment, the first boundary value a may be a negative integer and the second boundary value b may be a positive integer.

The control logic 520 may receive the disturb information DI for the first sub-block SB1, and the cell count change value ΔCC corresponding to the received disturb information DI may be zero. In accordance with an embodiment, the first boundary value a may be a negative integer and the second boundary value b may be a positive integer.

The control logic 520 may adjust the development time DT by maintaining the initial development time DTo, based on the feature that the cell count change value ΔCC corresponding to the disturb information DI is zero. In accordance with an embodiment, the control logic 520 may adjust the initial development time DTo to the adjusted development time and control the page buffer circuit 540 such that the read operation is performed based on the adjusted development time.

The control logic 520 may adjust the erase time ET by maintaining the initial erase time ETo, based on the feature that the cell count change value ΔCC corresponding to the disturb information DI is zero. In accordance with an embodiment, the control logic 520 may adjust the initial erase time ETo to the adjusted erase time, and control the page buffer circuit 540 and the voltage generator 550 such that the erase operation is performed based on the adjusted erase time.

By adjusting the operation time in operation S350, the non-volatile memory device 50 may perform the operation on the sub-block by reflecting that the threshold voltage of the memory cell in the sub-block is maintained.

When the cell count change value ΔCC) corresponding to the disturb information DI is equal to or less than the predetermined first boundary value a, the control logic 520 adjusts the operation time by decreasing the development time DT and the erase time ET (S360).

When the cell count change value ΔCC corresponding to the disturb information DI is equal to or less than the predetermined first boundary value a, it may imply that the distribution of the threshold voltage for the memory cell in the sub-block is decreased compared to the initial programmed status or the initial erased status. In accordance with an embodiment, the first boundary value a may be a negative integer.

In accordance with an embodiment, in the exemplary case where the cell count change value ΔCC corresponding to the received disturb information DI is the first cell count change value c1, the control logic may adjust the development time DT by decreasing the development time from the initial development time DTo to the first development time DT1. In accordance with an embodiment, the control logic 520 may adjust the first development time DT1 to the adjusted development time and control the page buffer circuit 540 such that the read operation is performed based on the adjusted development time.

In accordance with an embodiment, in the exemplary case where the cell count change value ΔCC corresponding to the received disturb information DI is the first cell count change value c1, the control logic 520 may adjust the erase time ET by descending the erase time from the initial erase time ETo to the first erase time ET1 based on the first cell count change value c1. In accordance with an embodiment, the control logic 520 may adjust the first erase time ET1 to the adjusted erase time and control the page buffer circuit 540 and the voltage generator 550 such that the erase operation is performed based on the adjusted erase time.

By adjusting the operation time in operation S360, the non-volatile memory device 50 may perform the operation on the sub-block by reflecting that the threshold voltages of the memory cells in the sub-block have been decreased due to the disturb, and may prevent data errors caused by the decrease of the threshold voltages.

The non-volatile memory device 50 may operate as in operations S310 to S360 above, and may perform the operation by adjusting the operation time OCb based on the disturb information DI. By adjusting the operation time OCb based on the disturb information DI, the non-volatile memory device 50 may perform the operation on the sub-block by reflecting the distribution shift of the threshold voltage varied by the operation of the adjacent sub-block, and may improve the reliability of the operation.

In accordance with an embodiment, the non-volatile memory device 50 may perform the operation by reflecting the distribution shift of the threshold voltage due to the disturb to reduce the occurrence of uncorrectable errors, and may reduce the number of occurrences of the operations of the read reclaim. Due to the reduction in the number of occurrences of the read reclamation operation, the storage device 30 may perform an operation responsive to the request of the host 20 while improving the delay caused by the read reclaim.

Although the operation of adjusting the operating voltage and the operation of adjusting the operating time are illustrated separately in FIGS. 1 to 21, the adjustment of the operating voltage and the adjustment of the operating time in the non-volatile memory device 50 may be performed together, depending on the embodiment.

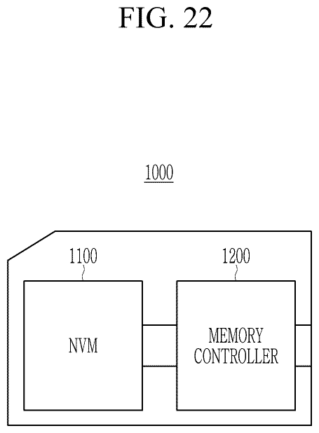

FIG. 22 is a block diagram illustrating a data storage device including the non-volatile memory device according to an embodiment. Referring to FIG. 22, the data storage device 1000 may include a non-volatile memory device 1100 and a memory controller 1200.

The memory controller 1200 may control the program/read/erase operation of the non-volatile memory device 1100 in response to a request from the outside.

As described in FIGS. 1 to 21, the memory controller 1200 may monitor the disturb circumstance based on the sub-blocks within the non-volatile memory device 1100, and the non-volatile memory device 1100 may generate disturb information for the sub-blocks based on the result of the monitoring and adjust the operating conditions based on the disturb information. Through the operation of FIGS. 1 to 21, the non-volatile memory device 1220 may improve reliability issues caused by the disturb phenomenon, and the data storage device 1000 may improve performance by reducing the number of occurrences of the read reclaim operation.

The data storage device 1000 may configure a memory card device, an SSD device, a multimedia card device, an SD device, a memory stick device, a hard disk drive device, a hybrid drive device, or a universal serial bus flash device. For example, the data storage device 1000 may configure a card for use with a user device, such as a digital camera and a personal computer.

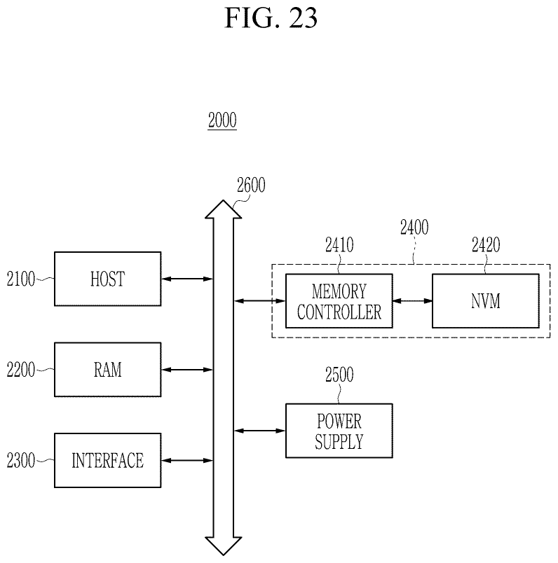

FIG. 23 is a block diagram illustrating a computer system including the non-volatile memory device according to the embodiment.

Referring to FIG. 23, a computer system 2000 may include a processor 2100, a RAM 2200, an interface device 2300, a memory system 2400, a power supply device 2500, and a bus 2600.

The processor 2100, the RAM 2200, the interface device 2300, the memory system 2400, and the power supply device 2500 may be coupled to each other via the bus 2600. The bus 2600 corresponds to a path through which data is moved.

The processor 2100 may include at least one of a microprocessor, a digital signal processor, a microcontroller, and logic elements capable of performing similar functions.

The RAM 2200 may be used as working memory to enhance the performance of the processor 2100. The interface device 2300 may perform functions to transmit data to a communication network or receive data from a communication network.

The interface device 2300 may be a wired form or a wireless form. For example, the interface device 2300 may include an antenna or a wired or wireless transceiver.

The memory system 2400 may store data and/or instructions, and the like. The memory system 2400 may include a memory controller 2410 and a non-volatile memory device 2420.

The memory controller 2410 may control program/read/erase operations of the non-volatile memory device 2420. The non-volatile memory device 2420 may include a plurality of non-volatile memory chips.

As described in FIGS. 1 to 21, the memory controller 2410 may monitor the disturb circumstance based on the sub-blocks within the non-volatile memory device 2420, and the non-volatile memory device 2420 may generate disturb information for the sub-blocks based on the result of the monitoring and adjust the operating conditions based on the disturb information. Through the operation of FIGS. 1 to 21, the non-volatile memory device 2420 may improve reliability issues caused by the disturb phenomenon, and the memory system 2400 may improve performance by reducing the number of occurrences of the read reclaim operation.

The power supply device 2500 may provide operational power for the processor 2100, the RAM 2200, the interface device 2300, and the memory system 2400.

The calculating system 2000 may be applied to a personal digital assistant (PDA), portable computer, web tablet, wireless phone, mobile phone, digital music player, memory card, or any electronic product capable of transmitting and/or receiving information in a wireless environment.

Although an embodiment of the present disclosure has been described in detail, the scope of the present disclosure is not limited by the embodiment. Various changes and modifications using the basic concept of the present disclosure defined in the accompanying claims by those skilled in the art shall be construed to belong to the scope of the present disclosure.

What is claimed is:

1. A non-volatile memory device comprising:
a memory cell array including first and second sub-blocks that are respectively formed from first and second portions of memory cell strings that extend through a plurality of wordlines stacked on a substrate, the first and second sub-blocks each being selectable as a unit of an erase operation; and
control logic configured to calculate an off-cell count based on a first voltage for a plurality of memory cells in the first sub-block, calculate an on-cell count based on a second voltage for the plurality of memory cells, and control an operation for the first sub-block to be performed based on an operating condition corresponding to disturb information generated by the off-cell count and the on-cell count.

2. The non-volatile memory device of claim 1, wherein:
the first sub-block includes a first wordline included in the plurality of wordlines,
the off-cell count is generated by calculating a change value in a memory cell determined to be an on-cell among a plurality of first memory cells connected to the first wordline based on the first voltage, and
the on-cell count is generated by calculating a change value of a memory cell determined to be an off-cell among the plurality of first memory cells based on the second voltage.

3. The non-volatile memory device of claim 1, wherein:
the control logic is configured to control, in response to receiving a read command, a read operation for the first sub-block to be performed based on an adjusted read voltage corresponding to the disturb information.

4. The non-volatile memory device of claim 1,
wherein the control logic is configured to:
adjust a first set of adjusted read voltages corresponding to the disturb information, and
control a read operation for the first sub-block based on the first set of adjusted read voltages, and
wherein when the disturb information implies a distribution increase in threshold voltages for the plurality of memory cells, each of the first set of adjusted read voltages adjusted by the control logic is respectively higher than a corresponding read voltage of a set of initial read voltages initially set.

5. The non-volatile memory device of claim 1, wherein:
the control logic is configured to control, in response to receiving an erase command, an erase operation for the first sub-block to be performed based on an adjusted erase voltage corresponding to the disturb information.

6. The non-volatile memory device of claim 5, wherein:
when the disturb information implies a distribution increase in a threshold voltage for the plurality of memory cells, the erase operation for the first sub-block is performed based on the adjusted erase voltage that is higher than an initial erase voltage initially set.

7. The non-volatile memory device of claim 5, wherein:
when the disturb information implies a distribution increase in a threshold voltage for the plurality of memory cells, the erase operation for the first sub-block is performed based on an adjusted erase time that is longer than an initial erase time initially set.

8. The non-volatile memory device of claim 1, wherein:
the disturb information includes a cell count change value calculated by subtracting the on-cell count from the off-cell count.

9. The non-volatile memory device of claim 1, wherein:
the plurality of memory cells are triple level cells (TLCs) configured to be programmed to one of an erased state and first to seventh states that are sequentially higher,
the first to the seventh states are divided by first to seventh program verification voltages that have sequentially higher voltage levels,
the first voltage is the first program verification voltage, and
the second voltage is the seventh program verification voltage.

10. A storage device comprising:
a non-volatile memory device including a memory cell array including first and second sub-blocks that are respectively formed from first and second portions of memory cell strings that extend through a plurality of wordlines stacked on a substrate, the first and second sub-blocks each being selectable as a unit of an erase operation, and control logic configured to generate disturb information for the first sub-block based on an on-cell count and an off-cell count for a plurality of memory cells in the first sub-block, and adjust an operating condition for the first sub-block based on the disturb information; and
a storage controller configured to log a first command for the second sub-block, and provide the non-volatile memory device with a disturb check command for the disturb information based on log information from a logging operation.

11. The storage device of claim 10, wherein:
the first and second sub-blocks are connected to a first bitline, and
when an erase operation is performed on the second sub-block, the first sub-block is floated.

12. The storage device of claim 11, wherein:
the storage controller is configured to provide the disturb check command to the non-volatile memory device based on first program/erase cycle log information for the first command and a predetermined value.

13. The storage device of claim 12, wherein:
the memory cell array further includes a third sub-block connected to the first bitline and divided from the first and second sub-blocks by the plurality of wordlines, and
the storage controller is further configured to log a second command for the third sub-block, compare the predetermined value with a sum of second program/erase cycle log information for the second command and the first program/erase cycle log information, and provide the disturb check command to the non-volatile memory device.

14. The storage device of claim 11, wherein:
the storage controller is configured to provide the disturb check command to the non-volatile memory device based on read log information for the first command and a predetermined value.

15. The storage device of claim 11, wherein:
in response to the erase operation being performed for the first sub-block, the log information is cleared.

16. The storage device of claim 10,
wherein the control logic is configured to:
generate the off-cell count by calculating a change value of a memory cell determined to be an on-cell based on a first voltage for the plurality of memory cells,
generate the on-cell count by calculating a change value of a memory cell determined to be an off-cell based on a second voltage for the plurality of memory cells, and
calculate the off-cell count and the on-cell count to generate the disturb information.

17. A method of operating a storage device, the method comprising:
logging a command of a first sub-block to monitor a disturb circumstance of a second sub-block connected to a first bitline connected to the first sub-block, wherein the first and second sub-blocks are respectively formed from first and second portions of memory cell strings that extend through a plurality of wordlines stacked on a substrate;
providing a disturb check command for the second sub-block based on a log operation for the command to a non-volatile memory device including the first and second sub-blocks;
generating disturb information by calculating based on an on-cell count and an off-cell count for a memory cell of a first wordline in the second sub-block;
storing the disturb information; and
performing an operation on the second sub-block based on an operating condition corresponding to the disturb information.

18. The method of claim 17, wherein:
the performing of the operation on the second sub-block includes:
receiving a read command for the second sub-block;
receiving the stored disturb information in response to receiving the read command; and
adjusting the operating condition based on the disturb information.

19. The method of claim 18, wherein:
the adjusting of the operating condition includes
when the disturb information implies a distribution increase in a threshold voltage for a plurality of memory cells, adjusting an initial read voltage to a read voltage that is higher than the initial read voltage.

20. The method of claim 18, wherein:
the adjusting of the operating condition includes
when the disturb information implies a distribution decrease in a threshold voltage for a plurality of memory cells, adjusting an initial read voltage to an adjusted read voltage that is lower than the initial read voltage.
